(19) United States
(12) Patent Application Publication
(10) Pub. No.: US 2026/0033060 A1
(43) Pub. Date: Jan. 29, 2026

(54) DISPLAY APPARATUS

(71) Applicant: LG Display Co., Ltd., Seoul (KR)

(72) Inventor: Bongseok Choi, Gyeonggi-do (KR)

(21) Appl. No.: 19/253,005

(22) Filed: Jun. 27, 2025

(30) Foreign Application Priority Data
Jul. 23, 2024 (KR) 10-2024-0096974

(51) Int. Cl. H10H 29/37; H01L 25/16; H10H 29/41; H10H 29/49; H10H 29/855

(52) U.S. Cl. CPC H10H 29/37; H01L 25/167; H10H 29/41; H10H 29/49; H10H 29/8552

(57) ABSTRACT

A display device includes a substrate including a display area and a non-display area, a pixel driving circuit in the display area on the substrate, an insulating layer on the pixel driving circuit, a plurality of banks including a first bank and a second bank, and a plurality of light emitting devices including a first light emitting device on the first bank and a second light emitting device on the second bank. The first bank and the second bank are disposed on the insulating layer. The first light emitting device overlaps the first bank and the second light emitting device overlaps the second bank. The insulating layer includes a groove in a region between the first bank and the first bank.

### CROSS-REFERENCE TO RELATED APPLICATIONS

Pursuant to 35 U.S.C. § 119(a), this application claims the benefit of an earlier filing date and right of priority to the Republic of Korea Patent Application No. 10-2024-0096974 filed on Jul. 23, 2024, which is hereby incorporated by reference in its entirety.

### TECHNICAL FIELD

The present disclosure relates to display devices.

### BACKGROUND

A display device can be implemented in various electronic devices such as TVs, mobile phones, laptops, and tablets.

Examples of the display devices include organic light emitting displays (OLEDs) that emit light by themselves and liquid crystal displays (LCDs) that require a separate light source.

### SUMMARY

In accordance with an aspect of the present disclosure, a display device may include a substrate including a display area and a non-display area, a pixel driving circuit in the display area on the substrate, an insulating layer on the pixel driving circuit, a plurality of banks including a first bank and a second bank, and a plurality of light emitting devices including a first light emitting device on the first bank and a second light emitting device on the second bank, wherein the first bank and the second bank are disposed on the insulating layer, wherein the first light emitting device overlaps the first bank and the second light emitting device overlaps the second bank, and wherein the insulating layer includes a groove in a region between the first bank and the first bank.

In accordance with another aspect of the present disclosure, a display device may include a display area, a non-display area disposed outside the display area, a plurality of pixels disposed in the display area and including a first sub-pixel and a second sub-pixel, a plurality of banks including a first bank in the first sub-pixel and a second bank in the second sub-pixel, and a plurality of light emitting devices including a first light emitting device overlapping the first bank and a second light emitting device overlapping the second bank, wherein the first sub-pixel and the second sub-pixel arranged in a first direction, and wherein a first groove is disposed in a region between the first sub-pixel and the second sub-pixel.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate implementations of the disclosure and together with the description serve to explain the principle of the disclosure.

FIG. 1 is an exploded perspective view of a display device according to an implementation of the present disclosure.

FIG. 2 is a plan view of a display device according to an implementation of the present disclosure.

FIG. 3 is an enlarged view of a display device according to an implementation of the present disclosure.

FIG. 4 is a diagram illustrating a circuit structure according to an implementation of the present disclosure.

FIG. 5 is a plan view of a display device according to an implementation of the present disclosure.

FIG. 6 is a plan view of a display device according to an implementation of the present disclosure.

FIG. 7 is a plan view of a display device according to an implementation of the present disclosure.

FIG. 8 is a cross-sectional view of a display device according to an implementation of the present disclosure.

FIG. 9 is a cross-sectional view of a display device according to an implementation of the present disclosure.

FIG. 10 is a process cross-sectional view illustrating a transfer process of a light emitting device according to an implementation of the present disclosure.

FIG. 11 is a process cross-sectional view illustrating a transfer process of a light emitting device according to an implementation of the present disclosure.

FIG. 12 is a cross-sectional view of a display device according to an implementation of the present disclosure, and relates to a display device to which the above-described transfer process according to FIG. 11 is applied.

FIG. 13 is a cross-sectional view of a display device according to an implementation of the present disclosure.

FIG. 14 is a plan view of a display device according to an implementation of the present disclosure.

FIG. 15 is a plan view of a display device according to an implementation of the present disclosure.

FIG. 16 is a plan view of a display device according to an implementation of the present disclosure.

FIG. 17 is a plan view of a display device according to an implementation of the present disclosure.

FIGS. 18 to 21 are diagrams illustrating devices to which a display device according to implementations of the present disclosure is applied.

Throughout the drawings and the detailed description, unless otherwise described, the same drawing reference numerals should be understood to refer to the same elements, features, and structures. The relative size and depiction of these elements may be exaggerated for clarity, illustration, and convenience

### DETAILED DESCRIPTION

Recently, a display device including a light emitting diode (LED) has attracted attention as a next-generation display device. The light emitting diode is made of an inorganic material, rather than an organic material. Accordingly, compared to the liquid crystal display or the organic light emitting display device, the display device including the light emitting diode has a faster lighting speed, excellent luminous efficiency, and displays an image having high luminance.

In the case of a display device including a light emitting device, a process of transferring a plurality of light emitting devices on a substrate is typically used. However, during the transfer process, an error may occur such that a light emitting device is not transferred to a desired position due to various reasons.

Implementations of the present disclosure can help address the above problems, for example, by providing a display device capable of reducing errors that may occur during a transfer process of light emitting devices.

Reference will now be made in detail to implementations of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following implementations described with reference to the accompanying drawings. The present disclosure may, however, be embodied in different forms and should not be construed as limited to the implementations set forth herein. Rather, these implementations are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing implementations of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only-’ is used. The terms of a singular form may include plural forms unless referred to the contrary.

In interpreting the components, it is interpreted as including the error range even if there is no separate explicit description of the error range.

In describing a position relationship, for example, when the position relationship is described as ‘upon’, ‘above’, ‘below’ and ‘next to’, one or more portions may be disposed between two other portions unless ‘just’ or ‘direct’ is used. The terms, such as “below,” “lower,” “above,” “upper” and the like, may be used herein to describe a relationship between element (s) as illustrated in the drawings. It will be understood that the terms are spatially relative and based on the orientation depicted in the drawings.

A description of a time relationship may include a case in which the temporal precedence relationship is described as “after”, “following”, or “before”, etc., and is not continuous unless “right away” or “directly”, is used.

Although the first, second, and the like are used to describe various components, these components are not limited by these terms. These terms are used only to distinguish one component from another. Therefore, a first component mentioned below may be a second component within a technical idea of a present disclosure.

It will be understood that, although the terms “first,” “second,” “A,” “B,” “(a),” and “(b)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

If a component is stated to be “connected,” “coupled,” “connected,” or “attached” to another component, that component may be connected, coupled, connected, or attached directly to that other component, but it should be understood that other components may be interposed between each component that may be connected, coupled, connected, or attached indirectly, without any specific description.

It should be understood that if a component or layer is stated to be “in contact” or “overlapping” with another component or layer, the component or layer may be in direct contact or overlapping with another component or layer, but other components may be interposed between each component that may be indirectly in contact or overlapping without particular explicit description.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

“First direction”, “second direction”, “third direction”, “X-axis direction”, “Y-axis direction”, and “Z-axis direction” should not be interpreted only as a geometric relationship perpendicular to each other, but may mean that the configuration of the present disclosure has a wider direction within a range in which the configuration of the present disclosure may functionally act.

Features of each of the various implementations of the present specification may be partially or entirely coupled or combined with each other, technically various interworking and driving are possible, and each of the implementations may be independently implemented with respect to each other or may be implemented together in a related relationship.

Hereinafter, one implementation of the present disclosure will be described in detail with reference to the accompanying drawings.

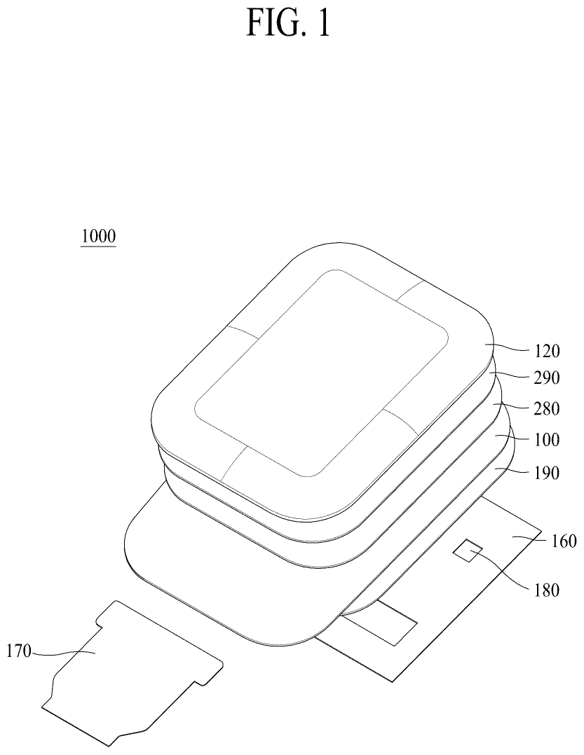

FIG. 1 is a perspective view illustrating a display device according to an implementation of the present disclosure.

Referring to FIG. 1, a display device 1000 according to an implementation of the present disclosure may include a display panel 100, a polarizing layer 280, an adhesive layer 290, a cover component 120, a support substrate 190, a flexible circuit board 170, and a printed circuit board 160.

The display panel 100 may display information, a video, and/or an image provided to a user.

The polarizing layer 280 may be disposed on the display panel 100. The polarizing layer 280 may prevent or reduce light generated from an external light source from entering the display panel 100 and affecting a light emitting element or the like.

The adhesive layer 290 may attach the cover component 120 to the display panel 100. The adhesive layer 290 may be disposed between the polarizing layer 280 and the cover component 120 to attach the cover component 120 to the polarizing layer 280. The adhesive layer 290 may include an optically clear adhesive (OCA), an optically clear resin (OCR), a pressure sensitive adhesive (PSA) or the like, but implementations of the present disclosure are not limited thereto.

The cover component 120 may be disposed on the polarizing layer 280. The cover component 120 may be disposed on the adhesive layer 290. The cover component 120 may be a component for protecting the display panel 100. The cover component 120 may be formed of a transparent material.

The support substrate 190 may be disposed between the display panel 100 and the printed circuit board 160. The support substrate 190 may reinforce rigidity of the display panel 100. The support substrate 190 may be a back plate, but implementations of the present disclosure are not limited thereto.

The flexible circuit board 170 and the printed circuit board 160 may be disposed on a bottom of the display panel 100. The flexible circuit board 170 and the printed circuit board 160 may be disposed on at least one edge of the display panel 100, but implementations of the present disclosure are not limited thereto. One side of the flexible circuit board 170 may be attached to the display panel 100, and the other side of the flexible circuit board 170 may be attached to the printed circuit board 160, but implementations of the present disclosure are not limited thereto. The flexible circuit board 170 may be a flexible film, but implementations of the present disclosure are not limited thereto.

The printed circuit board 160 may include at least one hole 180, but implementations of the present disclosure are not limited thereto. An internal component that senses ambient light or temperature, which may be provided to a plurality of sensors, may be disposed in an area corresponding to the at least one hole 180. For example, the internal component may include an ambient light sensor (ALS) or a temperature sensor, but implementations of the present disclosure are not limited thereto. For example, the hole 180 may be a through hole, etc., but implementations of the present disclosure are not limited thereto.

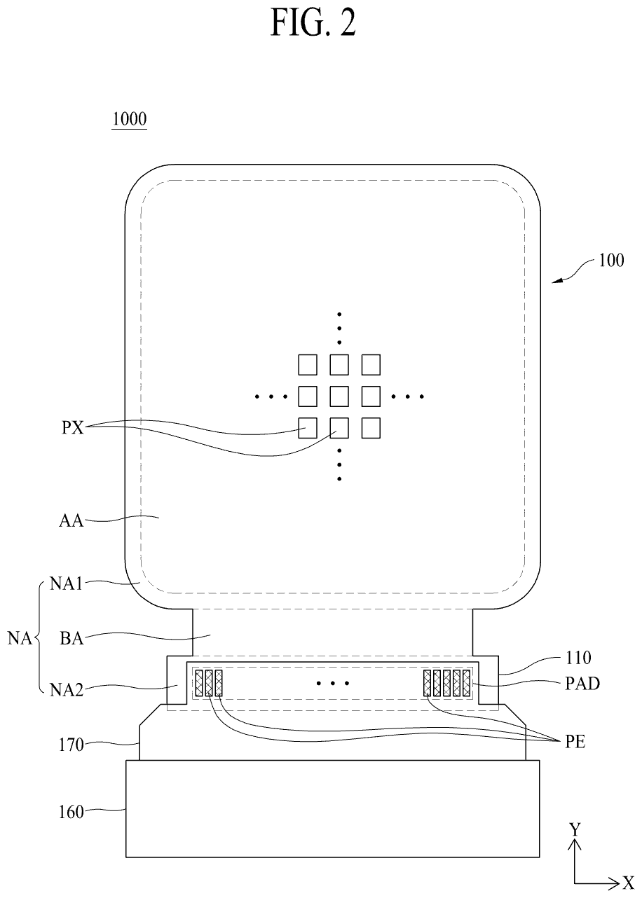

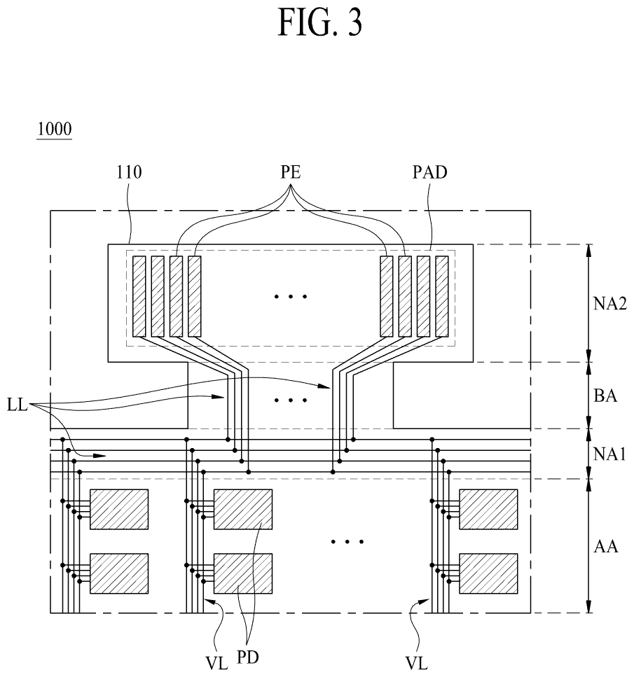

FIG. 2 is a plan view of a display device according to an implementation of the present disclosure. FIG. 3 is an enlarged view of a display device according to an implementation of the present disclosure.

Referring to FIGS. 2 and 3, the display device 1000 may include the display panel 100, the flexible circuit board 170, and the printed circuit board 160.

The display panel 100 may include a substrate 110. The substrate 110 may be a component that supports other components of the display device 1000. The substrate 110 may be made of an insulating material. For example, the substrate 110 may be made of glass or resin. Also, the substrate 110 may be made of a material having flexibility. For example, the substrate 110 may be made of a plastic material having flexibility, such as polyimide (PI). However, implementations of the present disclosure are not limited thereto.

For example, the display panel 100 may include a display area AA and a non-display area NA. For example, the substrate 110 may include the display area AA and the non-display area NA. The display area AA and the non-display area NA are not limited to the substrate 110 but may be described throughout the display device 1000.

The display area AA may be an area in which an image is displayed. The display area AA may include a plurality of pixels PX. Each of the plurality of pixels PX may include a plurality of sub-pixels. A plurality of light emitting elements may be disposed in each of the plurality of sub-pixels. A plurality of light emitting elements may be configured to be different according to a type of the display device 1000. For example, when the display device 1000 is an inorganic light emitting display device, the light emitting element may be a light-emitting diode (LED), a micro light-emitting diode (Micro-LED), or a mini-light-emitting diode (MLED), but implementations of the present disclosure are not limited thereto.

The display area AA may be configured in various shapes according to the design of the display device 1000. For example, the display area AA may be configured in a rectangular shape having four rounded corners, but configurations of the present disclosure are not limited thereto. For another example, the display area AA may be configured in a rectangular having four corners or circular shape, but configurations of the present disclosure are not limited thereto.

Referring to FIG. 3, a plurality of pixel driving circuits PD may be disposed in the display area AA. The plurality of pixel driving circuits PD may be circuits for driving light emitting elements of the plurality of sub-pixels. Each of the plurality of pixel driving circuits PD may include a plurality of transistors including driving transistors and storage capacitors. In addition, each of the plurality of pixel driving circuits PD may control a light emitting operation of the plurality of light emitting elements by supplying a control signal, a power source, and a driving current to the light emitting elements of the plurality of sub-pixels. For example, the pixel driving circuit PD may include a power line and a signal line for controlling light emission on/off and/or light emission time of the light emitting element. For example, the plurality of pixel driving circuits PD may be driving drivers manufactured using a metal-oxide-silicon field effect transistor (MOSFET) manufacturing process on a semiconductor substrate, but implementations of the present disclosure are not limited thereto. The driving driver includes the plurality of pixel driving circuits PD and may drive the plurality of sub-pixels.

The non-display area NA may be an area in which no image is displayed. Various wirings, circuits, and the like for driving the plurality of pixels PX of the display area AA may be disposed in the non-display area NA. For example, various wirings and driving circuits may be mounted in the non-display area NA. Also, a pad part PAD connected to an integrated circuit, a printed circuit, and the like may be disposed in the non-display area NA, but implementations of the present disclosure are not limited thereto.

For example, the driving circuit may be a data driving circuit and/or a gate driving circuit, but implementations of the present disclosure are not limited thereto. Wirings to which a control signal for controlling the driving circuits is supplied may be disposed in the non-display area NA. For example, the control signal may include various timing signals including a clock signal, an input data enable signal, and synchronization signals, but implementations of the present disclosure are not limited thereto. The control signal may be received through the pad part PAD. For example, link lines LL for transmitting a signal may be disposed in the non-display area NA. For example, a driving component such as the flexible circuit board 170 and the printed circuit board 160 may be connected to the pad part PAD.

According to the present disclosure, the non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1 and may be a bendable area. The second non-display area NA2 is an area extending from the bending area BA, and the pad part PAD may be disposed. For example, the bending area BA may be bent, and a remaining area of the substrate 110 except for the bending area BA may be flat. In this case, as the bending area BA is bent, the second non-display area NA2 may be disposed on a rear surface of the display area AA. However, implementations of the present disclosure are not limited thereto.

A plurality of link lines LL may be disposed in the non-display area NA. The plurality of link lines LL may be wirings for transmitting various signals from one or more flexible circuit boards (or flexible films) 170 and the printed circuit board 160 to the display area AA. The plurality of link lines LL may extend from a plurality of pad electrodes PE of the second non-display area NA2 toward the bending area BA and the first non-display area NA1, and may be electrically connected to a plurality of driving lines VL of the display area AA. The plurality of pixel driving circuits PD may be driven by receiving signals from one or more flexible circuit boards (or flexible films) 170 and the printed circuit board 160 through the driving line VL in the display area AA and the link line LL in the non-display area NA.

For example, the plurality of driving lines VL may be wirings for transmitting a signal output from the flexible circuit board (or flexible film) 170 and the printed circuit board 160 to the plurality of pixel driving circuits PD with the plurality of link lines LL. The plurality of driving lines VL may be disposed in the display area AA and electrically connected to each of the plurality of pixel driving circuits PD. The plurality of driving lines VL may extend from the display area AA toward the non-display area NA and may be electrically connected to the plurality of link lines LL. Accordingly, the signal output from the flexible circuit board (or flexible film) 170 and the printed circuit board 160 may be transmitted to each of the plurality of pixel driving circuits PD through the plurality of link lines LL and the plurality of driving lines VL.

As the bending area BA is bent, portions of the plurality of link lines LL may also be bent. Stress is concentrated on a portion of the bent link line LL, and thus, a crack may occur in the link line LL. Accordingly, the plurality of link lines LL may be formed of a conductive material having excellent ductility in order to reduce cracks when the bending area BA is bent. For example, the plurality of link lines LL may be formed of a conductive material having excellent ductility, such as gold (Au), silver (Ag), aluminum (Al), and the like, but implementations of the present disclosure are not limited thereto. Also, the plurality of link lines LL may be formed of one of various conductive materials used in the display area AA. For example, the plurality of link lines LL may be formed of molybdenum (Mo), chromium (Cr), titanium (Ti), nickel (Ni), neodymium (Nd), copper (Cu), an alloy of silver (Ag) and magnesium (Mg), or the like, but implementations of the present disclosure are not limited thereto. The plurality of link lines LL may be a multilayer structure including various conductive materials. For example, the plurality of link lines LL may be a triple layer structure including titanium (Ti), aluminum (Al), and titanium (Ti), but implementations of the present disclosure are not limited thereto.

A plurality of link lines LL may be configured in various shapes to reduce stress. At least a portion of the plurality of link lines LL disposed on the bending area BA may extend in a same direction as the extending direction of the bending area BA, or may extend in a direction different from the extending direction of the bending area BA to reduce stress. For example, when the bending area BA extends in one direction from the first non-display area NA1 to the second non-display area NA2, at least a portion of the link line LL disposed on the bending area BA may extend in a direction inclined to the one direction. For another example, at least a portion of the plurality of link lines LL may include patterns of various shapes. For example, at least a portion of the plurality of link lines LL disposed on the bending area BA may have a shape in which a conductive pattern having at least one of a diamond shape, a rhombus shape, a trapezoidal shape, a triangular wave shape, a sawtooth wave shape, a sinusoidal shape, a circular shape, and an omega shape is repeatedly arranged, but implementations of the present disclosure are not limited thereto. Therefore, in order to minimize the stress concentrated on the plurality of link lines LL and the corresponding crack, the shape of the plurality of link lines LL may be formed in various shapes including the above-described shape, but implementations of the present disclosure are not limited thereto.

According to the present disclosure, a width of the second non-display area NA2 in which the plurality of pad electrodes PE are disposed may be wider than a width of the bending area BA in which only the plurality of link lines LL is disposed. Also, a width of the display area AA in which the plurality of sub-pixels are disposed may be wider than the width of the bending area BA in which only the plurality of link lines LL are disposed. Although the width of the bending area BA is shown to be narrower than a width of other areas of the substrate 110, a shape of the substrate 110 including the bending area BA is exemplary, and implementations of the present disclosure are not limited thereto

A pad part PAD including a plurality of pad electrodes PE may be disposed in the second non-display area NA2. A driving component including one or more the flexible circuit boards (or flexible films) 170 and the printed circuit board 160 may be attached to or bonded to the pad part PAD. The plurality of pad electrodes PE of the pad part PAD are electrically connected to one or more flexible circuit boards (or flexible films) 170, and various signals (or power) received from the printed circuit board 160 and the flexible circuit board (or flexible film) 170 may be transmitted to the plurality of pixel driving circuits PD of the display area AA.

The flexible circuit board (or flexible film) 170 may be a film in which various components are disposed on a base film having flexibility. For example, a driving IC such as a gate driver IC or a data driver IC may be disposed on the flexible circuit board (or flexible film), but implementations of the present disclosure are not limited thereto. The driving IC may be a component that processes data and a driving signal for displaying an image. The driving IC may be disposed by a method of chip on glass (COG) or chip on film (COF) or a tape carrier package (TCP) depending on a method of being mounted, but implementations of the present disclosure are not limited thereto. The flexible circuit board (or flexible film) 170 may be attached to or bonded on the plurality of pad electrodes PE through a conductive adhesive layer, but implementations of the present disclosure are not limited thereto.

The printed circuit board 160 may be a component electrically connected to one or more flexible circuit boards (or flexible films) 170, and supplying signals to the driving IC. The printed circuit board 160 may be disposed on one side of the flexible circuit board (or flexible film) 170, and may be electrically connected to the flexible circuit board (or flexible film). Various components for supplying various signals to the driving IC may be disposed on the printed circuit board 160. For example, various components, such as a timing controller, a power supply unit, a memory, a processor, etc., may be disposed on the printed circuit board 160. For example, the printed circuit board 160 may include a power management integrated circuit (PMIC), but implementations of the present disclosure are not limited thereto.

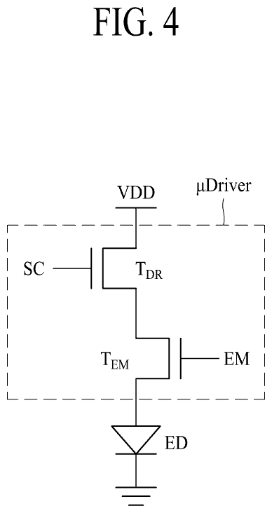

FIG. 4 is a diagram illustrating a circuit structure according to an implementation of the present disclosure.

FIG. 4 illustrates that one light emitting device ED is connected to one micro-driver(μ Driver), but is not limited thereto. For example, eight light emitting devices ED may be connected to one micro-driver(μ Driver). For another example, 16 light emitting devices ED may be connected to one micro-driver(μ Driver), 32 light emitting devices ED or 64 light emitting devices ED may be connected to one micro-driver(μ Driver) at the same time. The light emitting device ED may be a micro light emitting device(μ LED).

One micro-driver(Driver) may include a driving transistor T_{DR} and a light emitting transistor T_{EM}, but implementations of the present disclosure are not limited thereto.

For example, a high potential power voltage VDD may be applied to a first electrode of the driving transistor T_{DR}, a first electrode of the light emitting transistor TEM may be connected to a second electrode of the driving transistor T_{DR}, and a scan signal SC may be applied to a gate electrode of the driving transistor T_{DR}. The scan signal SC applied to the gate electrode of the driving transistor T_{DR} is a direct current power source, and a fixed reference voltage Vref may be applied to each frame, but implementations of the present disclosure are not limited thereto.

The second electrode of the driving transistor T_{DR} may be connected to a first electrode of the light emitting transistor T_{EM}, the light emitting device ED may be connected to a second electrode of the light emitting transistor T_{EM}, and a light emitting signal EM may be applied to a gate electrode of the light emitting transistor T_{EM}. The light emitting signal EM applied to the gate electrode of the light emitting transistor T_{EM} may be a pulse width modulation signal that changes every frame, but implementations of the present disclosure are not limited thereto.

A first electrode of the light emitting device ED may be connected to the second electrode of the light emitting transistor T_{EM}, and a second electrode of the light emitting device ED may be connected to ground. For example, the first electrode of the light emitting device ED may be an anode electrode, and the second electrode of the light emitting device ED may be a cathode electrode, but implementations of the present disclosure are not limited thereto.

Each of the driving transistor T_{DR} and the light emitting transistor T_{EM} may be an n-type transistor or a p-type transistor.

The driving transistor T_{DR} may be turned on by the scan signal SC applied from a timing controller T-CON in the micro-driver(μ Driver), and the light emitting transistor T_{EM} may be turned on by the light emitting signal EM. As a result, a driving current is applied to the light emitting device ED via the driving transistor T_{DR} and the light emitting transistor T_{EM} by the high potential power voltage VDD applied to the first electrode of the driving transistor T_{DR}, and thus the light emitting device ED may emit light.

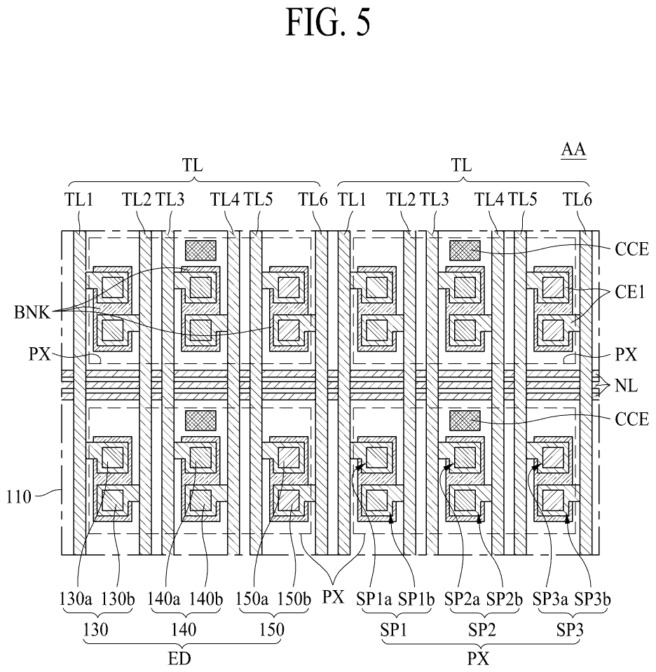

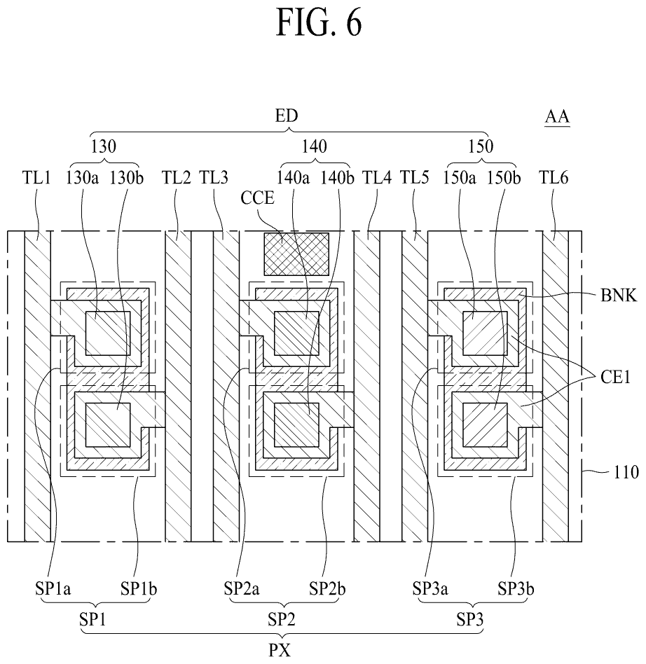

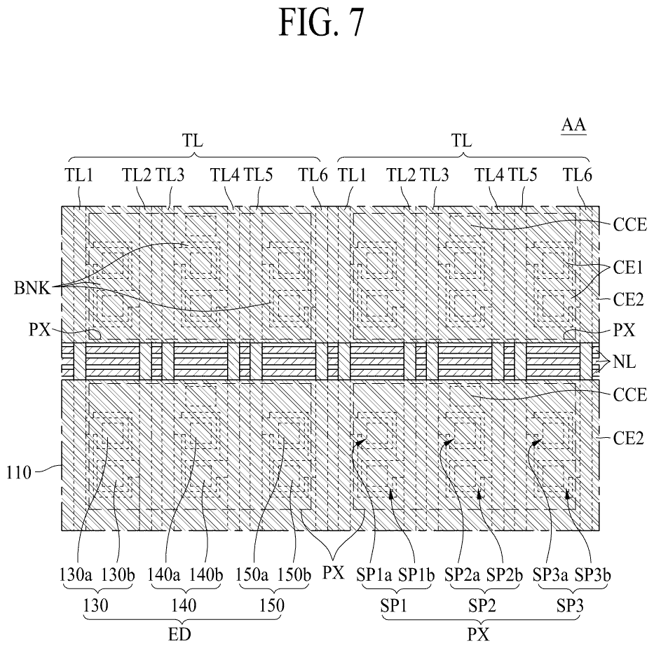

FIGS. 5 to 7 are plan views of a display device according to an implementation of the present disclosure. For example, FIG. 5 is an enlarged plan view of a display area including a plurality of pixels. For example, FIG. 6 is an enlarged plan view of a display area including one pixel. For example, FIG. 7 is an enlarged plan view of a display area including a plurality of pixels.

Although FIGS. 5 and 7 illustrate a plurality of signal lines TL, a plurality of communication lines NL, a plurality of first electrodes CE1, a plurality of banks BNK, and a plurality of light emitting devices ED, implementations of the present disclosure are not limited thereto. FIG. 7 is an enlarged plan view in which the plurality of second electrodes CE2 are additionally disposed in FIG. 5, for convenience, an area overlapping the second electrodes CE2 is indicated by a dotted line.

Referring to FIGS. 5 to 7, a plurality of pixels PX including a plurality of sub-pixels may be disposed in the display area AA. Each of the plurality of sub-pixels includes a light emitting device ED and may independently emit light. The plurality of sub-pixels may be arranged in a plurality of rows and a plurality of columns and may be disposed in a matrix form, but implementations of the present disclosure are not limited thereto.

The plurality of sub-pixels may include a first sub-pixel SP1, a second sub-pixel SP2, and a third sub-pixel SP3. For example, any one of the first sub-pixel SP1, the second sub-pixel SP2, and the third sub-pixel SP3 may be a red sub-pixel, another may be a green sub-pixel, and the other may be a blue sub-pixel. Types of the plurality of sub-pixels are examples, and implementations of the present disclosure are not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3. The pair of first sub-pixels SP1 may include a 1-1th sub-pixel SP1a and a 1-2th sub-pixel SP1b. The pair of second sub-pixels SP2 may include a 2-1th sub-pixel SP2a and a 2-2th sub-pixel SP2b. The pair of third sub-pixels SP3 may include a 3-ith sub-pixel SP3a and a 3-2th sub-pixel SP3b. For example, one pixel PX may include the 1-1th sub-pixel SP1a, the 1-2th sub-pixel SP2a, the 2-1th sub-pixel SP2a, the 2-2th sub-pixel SP2b, the 3-1th sub-pixel SP3a, and the 3-ith sub-pixel SP3b, but implementations of the present disclosure are not limited thereto.

The plurality of sub-pixels constituting one pixel PX may be variously arranged. For example, in one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of a plurality of sub-pixels constituting one pixel PX are examples, and implementations of the present disclosure are not limited thereto.

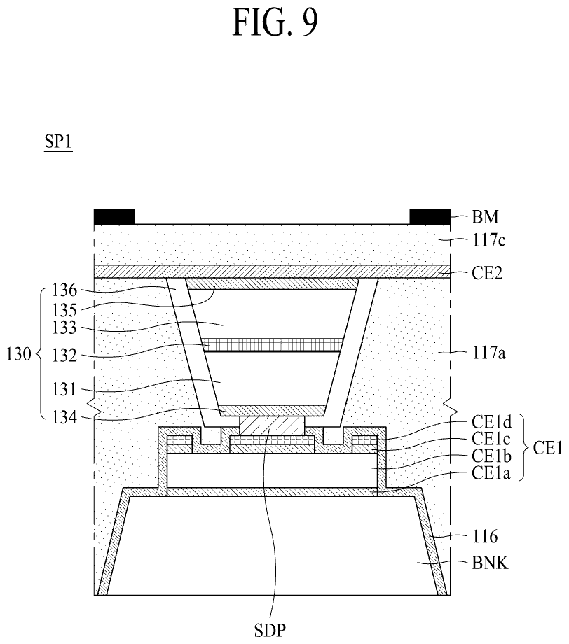

The plurality of signal lines TL may be disposed in an area between the plurality of sub-pixels. The plurality of signal lines TL may extend in a column direction between the plurality of sub-pixels. The plurality of signal lines TL may be lines that transmit the anode voltage from the pixel driving circuit PD (showed in FIG. 3) to the plurality of sub-pixels. For example, the plurality of signal lines TL may be electrically connected to the plurality of pixel driving circuits PD (showed in FIG. 3) and the first electrode CE1 of the plurality of sub-pixels. The anode voltage output from the pixel driving circuit PD (showed in FIG. 3) may be transmitted to the first electrode CE1 of the plurality of sub-pixels through the plurality of signal lines TL. For example, the first electrode CE1 may be an electrode electrically connected to the anode 134 of the light emitting device ED (showed in FIG. 9). Accordingly, the anode voltage from the signal line TL may be transmitted to the anode 134 of the light emitting device ED (showed in FIG. 9) through the first electrode CE1.

Therefore, instead of forming a plurality of transistors and storage capacitors in each of the plurality of sub-pixels, a structure of the display device 1000 may be simplified by using a pixel driving circuit PD (showed in FIG. 3) in which the plurality of pixel circuits are integrated in one pixel driving circuit PD (showed in FIG. 3). In addition, since a circuit disposed in each of the plurality of sub-pixels is integrated in one pixel driving circuit PD (showed in FIG. 3), high efficiency and low power driving may be possible.

The plurality of signal lines TL may include a first signal line TL1, a second signal line TL2, a third signal line TL3, a fourth signal line TL4, a fifth signal line TL5, and a sixth signal line TL6. Each of the first signal line TL1 and the second signal line TL2 may be electrically connected to each of the pair of first sub-pixels SP1. The third signal line TL3 and the fourth signal line TL4 may be electrically connected to each of the pair of second sub-pixels SP2. Each of the fifth signal line TL5 and the sixth signal line TL6 may be electrically connected to each of the pair of third sub-pixels SP3.

The first signal line TL1 may be disposed at one side of the pair of first sub-pixels SP1, and the second signal line TL2 may be disposed at the other side of the pair of first sub-pixels SP1. The first signal line TL1 may be electrically connected to one of the pair of first sub-pixels SP1, for example, the first electrode CE1 of the 1-1th sub-pixel SP1a. The second signal line TL2 may be electrically connected to the remaining first sub-pixel SP1 of the pair of first sub-pixels SP1, for example, the first electrode CE1 of the 1-2th sub-pixel SP1b.

The third signal line TL3 may be disposed at one side of the pair of second sub-pixels SP2, and the fourth signal line TL4 may be disposed at the other side of the pair of second sub-pixels SP2. For example, the third signal line TL3 may be disposed adjacent to the second signal line TL2. The third signal line TL3 may be electrically connected to one of the pair of second sub-pixels SP2, for example, the first electrode CE1 of the 2-1th sub-pixel SP2a. The fourth signal line TL4 may be electrically connected to the remaining second sub-pixel SP2 of the pair of second sub-pixels SP2, for example, the first electrode CE1 of the 2-2th sub-pixel SP2b.

The fifth signal line TL5 may be disposed at one side of the pair of third sub-pixels SP3, and the sixth signal line TL6 may be disposed at the other side of the pair of third sub-pixels SP3. For example, the fifth signal line TL5 may be disposed adjacent to the fourth signal line TL4. The sixth signal line TL6 may be disposed adjacent to the first signal line TL1 connected to the adjacent pixel PX. The fifth signal line TL5 may be electrically connected to one of the pair of third sub-pixels SP3, for example, the first electrode CE1 of the 3-1th sub-pixel SP3a. The sixth signal line TL6 may be electrically connected to the remaining third sub-pixel SP3 of the pair of third sub-pixels SP3, for example, the first electrode CE1 of the 3-2th sub-pixel SP3b.

The plurality of signal lines TL may be formed of a conductive material. For example, the plurality of signal lines TL may be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), etc., but implementations of the present disclosure are not limited thereto. For another example, the plurality of signal lines TL may be formed of a multilayer structure of a conductive material. For example, the plurality of signal lines TL may be formed of the multilayer structure in which titanium (Ti), aluminum (Al), titanium (Ti), and indium tin oxide (ITO) are stacked, but implementations of the present disclosure are not limited thereto.

The plurality of communication lines NL may be disposed in an area between the plurality of pixels PX. The plurality of communication lines NL may be disposed to extend in a row direction in an area between the plurality of pixels PX. The plurality of communication lines NL may be disposed in an area between the plurality of second electrodes CE2, and may not overlap the plurality of second electrodes CE2. For example, the plurality of communication lines NL may be wirings used for short-range communication such as near field communication (NFC). The plurality of communication lines NL may function as antennas. For example, the plurality of communication lines NL may be a plurality of connection lines, etc., but implementations of the present disclosure are not limited thereto.

According to the present disclosure, banks BNK may be disposed in each of the plurality of sub-pixels. The plurality of banks BNK may be structures in which the plurality of light emitting devices ED are disposed. The plurality of banks BNK may guide positions of the plurality of light emitting devices ED in a transfer process of the plurality of light emitting devices ED. The plurality of light emitting devices ED may be transferred onto the plurality of banks BNK in the transfer process of the plurality of light emitting devices ED. The plurality of banks BNK may be bank patterns or construction, but implementations of the present disclosure are not limited thereto.

The bank BNK of the first sub-pixel SP1, the bank BNK of the second sub-pixel SP2, and the bank BNK of the third sub-pixel SP3 may be disposed to be spaced apart from each other. The bank BNK of the first sub-pixel SP1, the bank BNK of the second sub-pixel SP2, and the bank BNK of the third sub-pixel SP3 may be configured to be separated. Accordingly, the bank BNK of the first sub-pixel SP1, the second sub-pixel SP2, and the third sub-pixel SP3 to which different types of light emitting devices ED are transferred may be easily identified.

The bank BNK of the 1-1th sub-pixel SP1a and the bank BNK of the 1-2th sub-pixel SP1b may be connected to each other or may be spaced apart from each other. For example, the bank BNK of the 1-1st sub-pixel SP1a and the bank BNK of the 1-2th sub-pixel SP1b in which the same light emitting device ED is disposed may be connected, separated, or spaced apart from each other in consideration of design such as transfer process requirements. The bank BNK of the 2-1th sub-pixel SP2a and the bank BNK of the 2-2th sub-pixel SP2b may be connected to each other or may be spaced apart from each other. The bank BNK of the 3-1th sub-pixel SP3a and the bank BNK of the 3-2th sub-pixel SP3b may be connected to each other or may be spaced apart from each other.

Accordingly, the bank BNK of the pair of first sub-pixels SP1, the bank BNK of the pair of second sub-pixels SP2, and the bank BNK of the pair of third sub-pixels SP3 may be variously formed, and implementations of the present disclosure are not limited thereto.

For example, the plurality of banks BNK may be formed of an organic insulating material. The plurality of banks BNK may be formed of a single layer or a multilayer of an organic insulating material. For example, the plurality of banks BNK may be formed of a photo resist, a polyimide (PI), an acryl-based material, or the like, but implementations of the present disclosure are not limited thereto.

The first electrode CE1 may be disposed in each of the plurality of sub-pixels. The first electrode CE1 may be disposed on the bank BNK. The first electrode CE1 may be electrically connected to one of the plurality of signal lines TL. At least a portion of the first electrode CE1 may extend to an outside of the bank BNK to be electrically connected to the signal line TL closest to the first electrode CE1. For example, a portion of the first electrode CE1 of the 1-1th sub-pixel SP1a may extend to one side area of the 1-1th sub-pixel SP1a to be electrically connected to the first signal line TL1, and a portion of the first electrode CE1 of the 1-2th sub-pixel SP1b may extend to the other side area of the 1-2th sub-pixel SP1b to be electrically connected to the second signal line TL2. A portion of the first electrode CE1 of the 2-1th sub-pixel SP2a may extend to one side area of the 2-ith sub-pixel SP2a to be electrically connected to the third signal line TL3, and a portion of the first electrode CE1 of the 2-2th sub-pixel SP2b may extend to the other side area of the 2-2th sub-pixel SP2b to be electrically connected to the fourth signal line TL4. A portion of the first electrode CE1 of the 3-1th sub-pixel SP3a may extend to one side area of the 3-1th sub-pixel SP3a to be electrically connected to the fifth signal line TL5, and a portion of the first electrode CE1 of the 3-2th sub-pixel SP3b may extend to the other side area of the 3-2th sub-pixel SP3b to be electrically connected to the sixth signal line TL6.

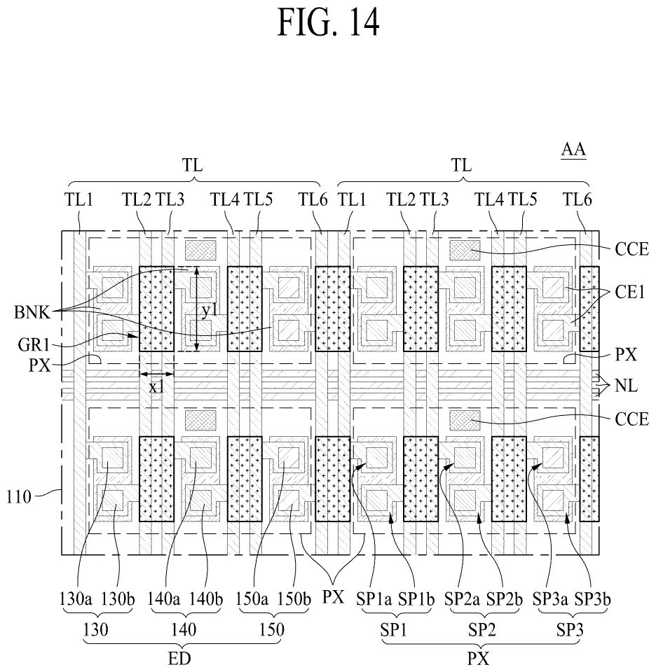

The first electrode CE1 is electrically connected to the anode electrode 134 (showed in FIG. 14) of the light emitting device ED. The anode voltage from the pixel driving circuit PD (showed in FIG. 3) may be transmitted to the light emitting device ED via the signal line TL and the first electrode CE1. A different voltage may be applied to the first electrode CE1 of each of the plurality of sub-pixels according to an image that is displayed. For example, different voltages may be applied to the first electrode CE1 of each of the plurality of sub-pixels. Accordingly, the first electrode CE1 may be a pixel electrode, and implementations of the present disclosure are not limited thereto.

The first electrode CE1 may be formed of a conductive material. For example, the first electrode CE1 may be formed integrally with the plurality of signal lines TLs. For example, the first electrode CE1 may be formed of the same conductive material as the plurality of signal lines TLs, but implementations of the present disclosure are not limited thereto. For example, the first electrode CE1 may be formed of the conductive material such as titanium (Ti), aluminum (Al), copper (Cu), molybdenum (Mo), nickel (Ni), chromium (Cr), indium tin oxide (ITO), indium zinc oxide (IZO), indium gallium zinc oxide (IGZO), and the like, but implementations of the present disclosure are not limited thereto. For another example, the first electrode CE1 may be formed of a multilayer structure of the conductive material. For example, the plurality of first electrodes CE1 may be formed of the multilayer structure in which titanium (Ti), aluminum (Al), titanium (Ti), and indium tin oxide (ITO) are stacked, but implementations of the present disclosure are not limited thereto.

The light emitting device ED may be disposed in each of a plurality of sub-pixels. The plurality of light emitting device ED may be any one of a light-emitting diode (LED) and a micro light-emitting diode (Micro LED), but implementations of the present disclosure are not limited thereto. The plurality of light emitting devices ED may be disposed on the bank BNK and the first electrode CE1. The plurality of light emitting devices ED may be disposed on the first electrode CE1 and may be electrically connected to the first electrode CE1. Accordingly, the light emitting device ED may emit light by receiving the anode voltage from the pixel driving circuit PD through the signal line TL and the first electrode CE1.

The plurality of light emitting devices ED may include a first light emitting device 130, a second light emitting device 140, and a third light emitting device 150. The first light emitting device 130 may be disposed in the first sub-pixel SP1. The second light emitting device 140 may be disposed in the second sub-pixel SP2. The third light emitting device 150 may be disposed in the third sub-pixel SP3. For example, one of the first light emitting device 130, the second light emitting device 140, and the third light emitting device 150 may be a red light emitting device, another may be a green light emitting device, and the other may be a blue light emitting device, but implementations of the present disclosure are not limited thereto. Accordingly, light of various colors including white may be implemented by combining red light, green light, and blue light emitted from the plurality of light emitting devices ED. Types of the plurality of light emitting devices ED are examples, and implementations of the present disclosure are not limited thereto.

The first light emitting device 130 may include a 1-1th light emitting device 130a disposed in the 1-1th sub-pixel SP1a and a 1-2th light emitting device 130b disposed in the 1-2th sub-pixel SP1b. The second light emitting device 140 may include a 2-ith light emitting device 140a disposed in the 2-1th sub-pixel SP2a and a 2-2th light emitting device 140b disposed in the 2-2th sub-pixel SP2b. The third light emitting device 150 may include a 3-ith light emitting device 150a disposed in the 3-1th sub-pixel SP3a and a 3-2th light emitting device 150b disposed in the 3-2th sub-pixel SP3b.

The second electrode CE2 may be disposed in each of the plurality of sub-pixels. The second electrode CE2 may be disposed on the light emitting device ED. The second electrode CE2 may be electrically connected to the pixel driving circuit PD (showed in FIG. 3) through a plurality of contact electrodes CCE.

For example, the second electrode CE2 may be electrically connected to the cathode electrode 135 (showed in FIG. 14) of the light emitting device ED to transmit the cathode voltage from the pixel driving circuit PD (showed in FIG. 3) to the light emitting device ED. The same cathode voltage may be applied to the second electrode CE2 of each of the plurality of sub-pixels. For example, the same voltage may be applied to the second electrode CE2 of each of the plurality of sub-pixels and the cathode electrode 135 (showed in FIG. 9) of the light emitting device ED. Accordingly, the second electrode CE2 may be a common electrode, but implementations of the present disclosure are not limited thereto.

At least some of the plurality of sub-pixels may share the second electrode CE2. Some of the second electrodes CE2 of each of the plurality of sub-pixels may be integrally formed to be electrically connected. When the same voltage is applied to the second electrode CE2, the second electrode CE2 of some of the sub-pixels may be shared and used. For example, the second electrodes CE2 of some of the pixels PX arranged in the same row in the horizontal direction may be integrally formed and connected to each other. For example, one second electrode CE2 may be disposed in the plurality of pixels PX. One second electrode CE2 may be disposed in every n sub-pixels.

For example, some of the second electrodes CE2 of each of the plurality of sub-pixels may be spaced apart from each other or to be separated from each other. For example, the second electrode CE2 connected to the pixels PX of the n-th row and the second electrode CE2 connected to the pixels PX of the n+1th row may be spaced apart from each other. For example, the plurality of second electrodes CE2 may be spaced apart from each other with the plurality of communication lines NL extending in a row direction interposed therebetween. Accordingly, the number of the plurality of sub-pixels may be greater than the number of the plurality of second electrodes CE2. For another example, all of the second electrodes CE2 of the plurality of sub-pixels may be integrally connected so that only one second electrode CE2 may be disposed on the substrate 110, and implementations of the present disclosure are not limited thereto.

The plurality of second electrodes CE2 may be formed of a transparent conductive material, but implementations of the present disclosure are not limited thereto. The plurality of second electrodes CE2 may be formed of the transparent conductive material so that light emitted from the light emitting device ED is directed to an upper portion of the second electrode CE2. For example, the second electrode CE2 may be formed of the transparent conductive material such as indium tin oxide (ITO), indium zinc oxide (IZO), indium gallium zinc oxide (IGZO), or the like, but implementations of the present disclosure are not limited thereto.

A plurality of contact electrodes CCE may be disposed on the substrate 110. For example, the plurality of contact electrodes CCE may be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit the cathode voltage from the pixel driving circuit PD (showed in FIG. 3) to the second electrode CE2.

For example, when a micro LED is used as the light emitting device ED, a plurality of micro LEDs may be formed in a wafer and the micro LEDs may be transferred to the substrate 110 to manufacture the display panel 100. Various defects may occur in the process of transferring the plurality of light emitting devices ED having a micro size from the wafer to the substrate 110. For example, a non-transmission defect in which the light emitting device ED is not transferred may occur in some sub-pixels, and a defect in which the light emitting device ED is transferred out of a desired position due to an alignment error may occur in some sub-pixels. Also or instead, the transfer process might have been able to proceed normally, but the transferred light emitting device ED itself may be defective. Accordingly, the plurality of the same light emitting devices ED may be transferred to one sub-pixel while accounting for the defect during the transfer process of the plurality of light emitting devices ED. After the lighting test of the plurality of light emitting devices ED is performed, only one light emitting device ED finally determined to be normal may be used.

For example, the 1-1th light emitting device 130a and the 1-2th light emitting device 130b may be transferred to one pixel PX, and it is possible to inspect whether there is a defect in the 1-ith light emitting device 130a and the 1-2th light emitting device 130b. If both of the 1-1th light emitting device 130a and the 1-2th light emitting device 130b are determined to be normal, only the 1-1th light emitting device 130b may be used and the 1-2th light emitting device 130b may be not used. As another example, if only the 1-2th light emitting device 130b of the 1-1th light emitting device 130a and the 1-2th light emitting device 130b is determined to be normal, the 1-ith light emitting device 130a may not be used and only the 1-2th light emitting device 130b may be used. Therefore, even if the plurality of the same light emitting devices ED are transferred to one pixel PX, only one light emitting device ED may be finally used.

Accordingly, any one of the pair of light emitting devices ED may be a main or primary light emitting device ED, and the other light emitting device ED may be a redundancy light emitting device ED. The redundancy light emitting device ED may be an extra light emitting device ED transferred to prepare for a defect in the main light emitting device ED. When the main light emitting device ED is defective, the redundancy light emitting device ED may be used instead of the main light emitting device ED. Accordingly, the main light emitting device ED and the redundancy light emitting device ED are transferred to one pixel PX, thereby minimizing deterioration of display quality due to defects in the main light emitting device ED and the redundancy light emitting device ED.

For example, the 1-1th light emitting device 130a, the 2-1th light emitting device 140a, and the 3-1th light emitting device 150a transferred to one pixel PX may be used as the main light emitting device ED, and the 1-2th light emitting device 130b, the 2-2th light emitting device 140b, and the 3-2th light emitting device 150b may be used as the redundancy light emitting device ED.

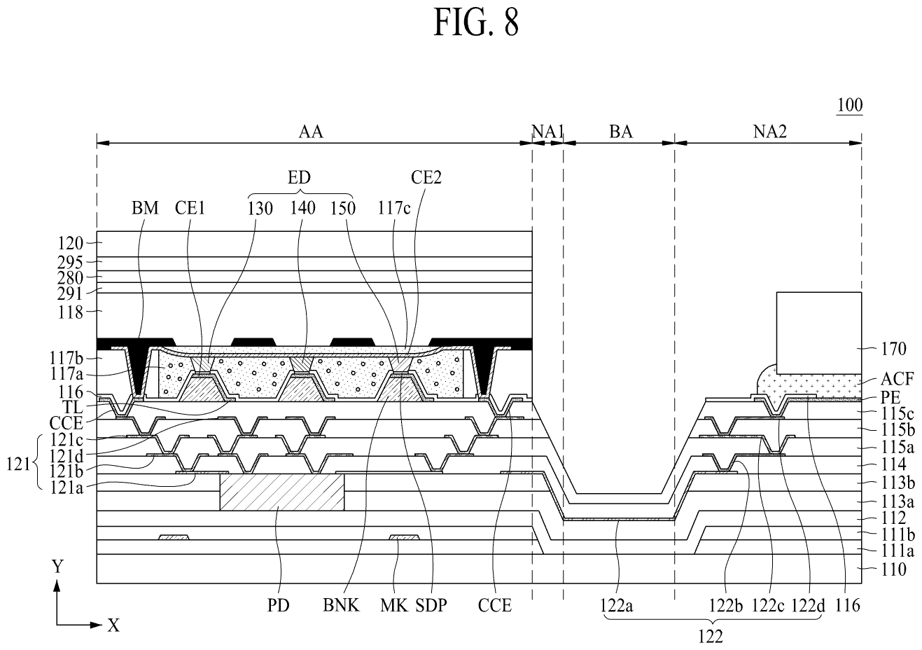

FIG. 8 is a cross-sectional view of a display device according to an implementation of the present disclosure. FIG. 9 is a cross-sectional view of a display device according to an implementation of the present disclosure. For example, FIG. 8 is a cross-sectional view of the display area AA, the first non-display area NA, the bending area BA, and the second non-display area NA2, and FIG. 9 is a cross-sectional view of a portion of the display area AA.

Referring to FIG. 8, a first buffer layer 111a and a second buffer layer 111b may be disposed in the remaining area of the substrate 110 except the bending area BA.

The first buffer layer 111a and the second buffer layer 111b may be disposed in the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be formed of an inorganic insulating material. For example, the first buffer layer 111a and the second buffer layer 111b may be formed of a single layer or a multilayer composed of silicon oxide (SiOx) or silicon nitride (SiNx), but implementations of the present disclosure are not limited thereto.

For example, portions of the first buffer layer 111a and the second buffer layer 111b on the bending area BA may be removed. An upper surface of the substrate 110 disposed in the bending area BA may be exposed by the first buffer layer 111a and the second buffer layer 111b. The first buffer layer 111a and the second buffer layer 111b made of the inorganic insulating material may be removed from the bending area BA, thereby minimizing cracks in the first buffer layer 111a and the second buffer layer 111b that may occur during bending.

A plurality of alignment keys MK may be disposed between the first buffer layer 111a and the second buffer layer 111b. The plurality of alignment keys MK may be identify a position of the pixel driving circuit PD during a manufacturing process of the display panel 100. For example, the plurality of alignment keys MK may align the position of the pixel driving circuit PD transferred onto an adhesive layer 112. For another example, the plurality of alignment keys MK may be omitted.

An adhesive layer 112 may be disposed on the second buffer layer 111b. The adhesive layer 112 may be disposed in the display area AA, the first non-display area NA1, the bending area BA, and the second non-display area NA2. For another example, a portion of the adhesive layer 112 may be removed from the non-display area NA including the bending area BA. For example, the adhesive layer 112 may be formed of any one of an Adhesive polymer, an epoxy resin, a UV curable resin, a polyimide-based resin, an acrylate-based material, a urethane-based material, and a polydimethylsiloxane (PDMS), but implementations of the present disclosure are not limited thereto.

In the display area AA, the pixel driving circuit PD may be disposed on the adhesive layer 112. When the pixel driving circuit PD is implemented as a driving driver, the driving driver may be mounted on the adhesive layer 112 through a transfer process, but implementations of the present disclosure are not limited thereto.

A first protective layer 113a and a second protective layer 113b may be disposed on the adhesive layer 112 and the pixel driving circuit PD. The first protective layer 113a and the second protective layer 113b may surround a side surface of the pixel driving circuit PD, but implementations of the present disclosure are not limited thereto. For example, the second protective layer 113b may cover at least a portion of a upper surface of the pixel driving circuit PD. For example, at least one of the first protective layer 113a and the second protective layer 113b disposed on the bending area BA may be omitted. For example, the first protective layer 113a is entirely disposed in the display area AA and the non-display area NA, and the second protective layer 113b is partially disposed in the display area AA, the first non-display area NA1, and the second non-display area NA2 and may not be disposed in the bending area BA. For example, a portion of the second protective layer 113b in the bending area BA may be removed. However, implementations of the present disclosure are not limited thereto.

The first protective layer 113a and the second protective layer 113b may be formed of an organic insulating material, but implementations of the present disclosure are not limited thereto. For example, the first protective layer 113a and the second protective layer 113b may be formed of a photo resist, polyimide (PI), a photoacryl-based material, or the like, but implementations of the present disclosure are not limited thereto. For example, the first protective layer 113a and the second protective layer 113b may be an overcoating layer or an insulating layer, but implementations of the present disclosure are not limited thereto.

According to the present disclosure, a plurality of first connection lines 121 may be disposed on the second protective layer 113b in the display area AA. The plurality of first connection lines 121 may be wirings for electrically connecting the pixel driving circuit PD to other elements. For example, the pixel driving circuit PD may be electrically connected to the plurality of signal lines TL, the plurality of contact electrodes CCE, and the like through the plurality of first connection lines 121. For example, the plurality of first connection lines 121 may include a plurality of 1-1th connection lines 121a, a plurality of 1-2th connection lines 121b, a plurality of 1-3th connection lines 121c, and a plurality of 1-4th connection lines 121d, but implementations of the present disclosure are not limited thereto.

For example, the plurality of 1-1th connection lines 121a may be disposed on the second protective layer 113b. The plurality of 1-1th connection lines 121a may be electrically connected to the pixel driving circuit PD. The plurality of 1-1th connection lines 121a may transmit voltages output from the pixel driving circuit PD to the first electrode CE1 or the second electrode CE2.

For example, a third protective layer 114 may be disposed on the second protective layer 113b. The third protective layer 114 may be disposed on the entire display area AA and the non-display area NA. In the bending area BA, the third protective layer 114 may disposed on or cover a side surface of the second protective layer 113b and an upper surface of the first protective layer 113a. The third protective layer 114 may be formed of an organic insulating material. For example, the third protective layer 114 may be formed of a photo resist, polyimide (PI), a photoacryl-based material, or the like, but implementations of the present disclosure are not limited thereto. For example, the first protective layer 113a, the second protective layer 113b, and the third protective layer 114 may be formed of the same material, but implementations of the present disclosure are not limited thereto.

The plurality of 1-2th connection lines 121b may be disposed on the third protective layer 114. The plurality of 1-2th connection lines 121b may be connected to the pixel driving circuit PD through the 1-1th connection lines 121a or may be directly connected to the pixel driving circuit PD. For example, a portion of the 1-2th connection line 121b may be directly connected to the pixel driving circuit PD through a contact hole of the third protective layer 114. The other portion of the 1-2th connection line 121b may be electrically connected to the 1-1th connection line 121a through a contact hole of the third protective layer 114. However, implementations of the present disclosure are not limited thereto. For example, the voltage output from the pixel driving circuit PD may be transmitted to the first electrode CE1 or the second electrode CE2 through connection lines different from the plurality of 1-2th connection lines 121b.

A first insulating layer 115a may be disposed on the plurality of 1-2th connection lines 121b. The first insulating layer 115a may be disposed in the entire display area AA and the non-display area NA, but implementations of the present disclosure are not limited thereto. The first insulating layer 115a may be formed of an organic insulating material, but implementations of the present disclosure are not limited thereto. For example, the first insulating layer 115a may be formed of a photo resist, polyimide (PI), a photoacryl-based material, or the like, but implementations of the present disclosure are not limited thereto.

The plurality of 1-3th connection lines 121c may be disposed on the first insulating layer 115a. The plurality of 1-3th connection lines 121c may be electrically connected to the plurality of 1-2th connection lines 121b. For example, the 1-3th connection lines 121c may be electrically connected to the 1-2th connection lines 121b through a contact hole of the first insulating layer 115a.

A second insulating layer 115b may be disposed on the plurality of 1-3th connection lines 121c. The second insulating layer 115b may be disposed in the remaining area except for the bending area BA, but implementations of the present disclosure are not limited thereto. The second insulating layer 115b may be disposed in the display area AA, the first non-display area NA1, and the second non-display area NA2, but implementations of the present disclosure are not limited thereto. For example, at least a portion of the second insulating layer 115b disposed in the bending area BA may be removed. The second insulating layer 115b may be formed of an organic insulating material, but implementations of the present disclosure are not limited thereto. For example, the second insulating layer 115b may be formed of a photo resist, polyimide (PI), a photoacryl-based material, or the like, but implementations of the present disclosure are not limited thereto.

The plurality of 1-4th connection lines 121d may be disposed on the second insulating layer 115b. The plurality of 1-4th connection lines 121d may be electrically connected to the plurality of 1-3th connection lines 121c. For example, the 1-4th connection lines 121d may be electrically connected to the 1-3th connection lines 121c through a contact hole of the second insulating layer 115b.

The 1-4th connection line 121d may be connected to the contact electrode CCE through a contact hole of the third insulating layer 115c. Accordingly, the contact electrode CCE and the pixel driving circuit PD may be electrically connected to each other by the first connection line 121.

Although not shown, the 1-4th connection line 121d may be directly connected to the signal line TL through a contact hole disposed in the third insulating layer 115c, or may be electrically connected to the signal line TL through other additional lines or electrodes. Accordingly, the signal line TL and the pixel driving circuit PD may be electrically connected by the first connection line 121.

According to the present disclosure, a plurality of second connection lines 122 may be disposed on the second protective layer 113b in the non-display area NA. The plurality of second connection lines 122 may be wirings for transmitting a signal received from the flexible circuit board (or a flexible film) 170 (showed in FIG. 2) and a printed circuit board 160 (showed in FIG. 2) to the pixel driving circuit PD of the display area AA.

For example, the plurality of second connection lines 122 may be electrically connected to the plurality of pad electrodes PE to receive signals from flexible circuit boards (or flexible films) 170 (showed in FIG. 2) and printed circuit boards 160 (showed in FIG. 2).

For example, the plurality of second connection lines 122 may extend from the pad part PAD (showed in FIG. 2) toward the display area AA to transmit signals to the wirings of the display area AA. In this case, the plurality of second connection lines 122 may function as link lines LL (showed in FIG. 3). The plurality of second connection lines 122 may include a 2-1th connection line 122a, a 2-2th connection line 122b, a 2-3th connection line 122c, and a 2-4th connection line 122d.

The plurality of 2-1th connection lines 122a may be disposed on the second protective layer 113b. The plurality of 2-1th connection lines 122a may extend from the second non-display area NA2 to the bending area BA and the first non-display area NA1. The plurality of 2-1 connection lines 122a may transmit signals received from the flexible circuit board (or flexible film 170 (showed in FIG. 2) and the printed circuit board 160 (showed in FIG. 2) to the pixel driving circuit PD of the display area AA. Accordingly, the plurality of 2-1th connection lines 122a may be electrically connected to the pad electrode PE and the pixel driving circuit PD, respectively.

For example, although not shown, the 2-1th connection line 122a may extend to the display area AA to be directly connected to the pixel driving circuit PD in the display area AA, or may be electrically connected to the pixel driving circuit PD through other additional line or electrodes. In addition, the 2-1th connection line 122a may be electrically connected to the pad electrode PE in the second non-display area NA2 via the 2-2th connection line 122b, the 2-3th connection line 122c, and the 2-4th connection line 122d. Accordingly, the pixel driving circuit PD and the pad electrode PE may be electrically connected to each other by the second connection line 122.

The plurality of 2-2th connection lines 122b may be disposed on the third protective layer 114. The plurality of 2-2th connection lines 122b may be disposed in the second non-display area NA2. The 2-2 connection lines 122b may be electrically connected to the 2-1th connection lines 122a through a contact hole of the third protective layer 114. Therefore, signals from the flexible circuit board (or flexible film) 170 (showed in FIG. 2) and the printed circuit board 160 (showed in FIG. 2) may be transmitted to the 2-1 connection lines 122a through the 2-2 connection lines 122b.

The 2-3th connection line 122c may be disposed on the first insulating layer 115a. The 2-3th connection line 122c may be disposed in the second non-display area NA2. The 2-3th connection line 122c may be electrically connected to the 2-2th connection line 122b through a contact hole of the first insulating layer 115a. Accordingly, signals from the flexible circuit board (or flexible film) 170 (showed in FIG. 2) and the printed circuit board 160 (showed in FIG. 2) may be transmitted to the 2-1th connection line 122a through the 2-3th connection line 122c and the 2-2th connection line 122b.

The 2-4th connection line 122d may be disposed on the second insulating layer 115b. The 2-4th connection line 122d may be disposed in the second non-display area NA2. The 2-4th connection line 122d may be electrically connected to the 2-3th connection line 122c through a contact hole of the second insulating layer 115b. The 2-4th connection line 122d may be electrically connected to the pad electrode PE through a contact hole of the third insulating layer 115c.

Accordingly, signals from the flexible circuit board (or flexible film) 170 (showed in FIG. 2) and the printed circuit board 160 (showed in FIG. 2) may be transmitted to the 2-1th connection line 122a through the 2-4th connection line 122d, the 2-3th connection line 122c, and the 2-2 connection line 122b.

The plurality of first connection lines 121 and the plurality of second connection lines 122 may be formed of a conductive material having excellent ductility or various conductive materials used in the display area AA. For example, the second connection line 122 partially disposed in the bending area BA may be formed of a conductive material having excellent ductility, such as gold (Au), silver (Ag), or aluminum (Al), but implementations of the present disclosure are not limited thereto. For another example, the plurality of first connection lines 121 and a plurality of second connection lines 122 may be formed of molybdenum (Mo), chromium (Cr), titanium (Ti), nickel (Ni), neodymium (Nd), copper (Cu), an alloy of silver (Ag) and magnesium (Mg), or an alloy thereof, but implementations of the present disclosure are not limited thereto.

A third insulating layer 115c may be disposed on the plurality of first connection lines 121 and the plurality of second connection lines 122. The third insulating layer 115c may be disposed in the remaining area except for the bending area BA, but implementations of the present disclosure are not limited thereto. The third insulating layer 115c may be disposed in the display area AA, the first non-display area NA1, and the second non-display area NA2. At least a portion of the third insulating layer 115c in the bending area BA may be removed. The third insulating layer 115c may be formed of an organic insulating material, but implementations of the present disclosure are not limited thereto. For example, the third insulating layer 115c may be formed of a photo resist, polyimide (PI), a photo acryl-based material, or the like, but implementations of the present disclosure are not limited thereto.

A plurality of banks BNK may be disposed on the third insulating layer 115c in the display area AA. The plurality of banks BNK may overlap each of the plurality of sub-pixels. The plurality of banks BNK may not be disposed in the first non-display area NA1, the second non-display area NA2, and the bending area BA. One or more light emitting devices ED of the same type may be disposed on an upper portion of each of the plurality of banks BNK.

In the display area AA, a plurality of signal lines TLs may be disposed on the third insulating layer 115c. The plurality of signal lines TLs may be disposed between the plurality of banks BNK. For example, the plurality of signal lines TLs may be disposed adjacent to any one of the plurality of banks BNK. Each of the plurality of signal lines TLs may be electrically connected to the first connection line 121, for example, the 1-4th connection line 121d.

A plurality of contact electrodes CCE may be disposed on the third insulating layer 115c in the display area AA. The plurality of contact electrodes CCE may supply the cathode voltage from the pixel driving circuit PD to the second electrode CE2. Each of the plurality of contact electrodes CCE may be electrically connected to the first connection line 121, for example, the 1-4th connection line 121d.

A first electrode CE1 may be disposed on the bank BNK. For example, the first electrode CE1 may extend from the adjacent signal line TL to an upper portion of the bank BNK. The first electrode CE1 may be disposed on an upper surface of the bank BNK and a side surface of the bank BNK. For example, the first electrode CE1 may extend from the signal line TL on an upper surface of the third insulating layer 115c to the side surface of the bank BNK and the upper surface of the bank BNK. The first electrode CE1 may be integrally formed with the signal line TL.

Referring to FIG. 9, the first electrode CE1 may include a plurality of conductive layers. For example, the first electrode CE1 may include a first conductive layer CE1a, a second conductive layer CE1b, a third conductive layer CE1c, and a fourth conductive layer CE1d, but implementations of the present disclosure are not limited thereto.

The first conductive layer CE1a may be disposed on the bank BNK. The second conductive layer CE1b may be disposed on the first conductive layer CE1a. The third conductive layer CE1 may be disposed on the second conductive layer CE1b, and the fourth conductive layer CE1d may be disposed on the third conductive layer CE1c. For example, the first conductive layer CE1a, the second conductive layer CE1b, the third conductive layer CE1c, and the fourth conductive layer CE1d may be formed of titanium (Ti), molybdenum (Mo), aluminum (Al), or titanium (Ti) and indium tin oxide (ITO), but implementations of the present disclosure are not limited thereto.

According to the present disclosure, some of the plurality of conductive layers included in the first electrode CE1 having high reflection efficiency may be composed of an alignment key and/or a reflector for aligning the light emitting device ED. For example, the second conductive layer CE1b among the plurality of conductive layers of the first electrode CE1 may include a reflective material. For example, the second conductive layer CE1b may include aluminum (Al), but implementations of the present disclosure are not limited thereto. Thus, the second conductive layer CE1b may be used as a reflective plate. Also, due to a high reflection efficiency of the second conductive layer CE1b, identification may be easily performed in a manufacturing process, and thus an arrangement position or a transfer position of the light emitting device ED with respect to the second conductive layer CE1b.

For example, in order to use the second conductive layer CE1b as the reflective plate, the third conductive layer CE1c and the fourth conductive layer CE1d covering the second conductive layer CE1b may be partially removed or etched. For example, portions of the third and fourth conductive layers CEic and CE1d disposed on the bank BNK may be removed or etched to expose an upper surface of the second conductive layer CE1b. For example, a central portion and an edge portion of the third and fourth conductive layers CE1c and CE1d on which a solder pattern SDP is disposed may remain, and remaining portions except for the center portion of the third and fourth conductive layers CE1c and CE1d may be removed. For example, the central portion and the edge portion of each of the third conductive layer CE1 made of titanium (Ti) and the fourth conductive layer CE1d made of indium tin oxide (ITO) may not be etched. Thus, another conductive layer of the first electrode CE1 may be prevented from being corroded by a TMAH (Tetra Methyl Ammonium Hydroxide) solution used in a mask process of the first electrode CE1.

According to the present disclosure, the first conductive layer CE1a and the third conductive layer CEle may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has high adhesion to the solder pattern SDP and has corrosion resistance and acid resistance. However, implementations of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but implementations of the present disclosure are not limited thereto.

As shown in FIGS. 8 and 9, according to the present disclosure, the signal line TL, the contact electrode CCE, and the pad electrode PE disposed on the same layer as the first electrode CE1 may be formed of multiple layers of conductive materials, but implementations of the present disclosure are not limited thereto. For example, the signal line TL, the contact electrode CCE, and the pad electrode PE may be formed of multiple layers in which indium tin oxide (ITO), titanium (Ti), aluminum (Al), and titanium (Ti) are stacked, but implementations of the present disclosure are not limited thereto.

According to the present disclosure, a solder pattern SDP may be disposed on the first electrode CE1 in each of the plurality of sub-pixels. The solder pattern SDP may bond the light emitting device ED to the first electrode CEL1. The first electrode CEL1 and the light emitting device ED may be electrically connected to each other through eutectic bonding using the solder pattern SDP, but implementations of the present disclosure are not limited thereto. For example, when the solder pattern SDP is formed of indium (In), and the anode electrode 134 of the light emitting device ED is formed of gold (Au), the solder pattern SDP and the anode electrode 134 may be bonded to each other by applying heat and pressure in the transfer process of the light emitting device ED. The light emitting device ED may be bonded to the solder pattern SDP and the first electrode CE1 without a separate adhesive component through eutectic bonding. For example, the solder pattern SDP may be formed of indium (In), tin (Sn), or alloys thereof, but implementations of the present disclosure are not limited thereto. For example, the solder pattern SDP may be a bonding pad, a contact pad, or the like, but implementations of the present disclosure are not limited thereto.

According to the present disclosure, a passivation layer 116 may be disposed on the plurality of signal lines TL, the plurality of first electrodes CE1, the plurality of contact electrodes CCE, and the third insulation layer 115c. For example, the passivation layer 116 may be disposed in the display area AA, the first non-display area NA1, and the second non-display area NA2. A portion of the passivation layer 116 disposed in the bending area BA may be removed. A portion of the passivation layer 116 covering the plurality of pad electrodes PE may be removed in the second non-display area NA2. A portion of the passivation layer 116 covering the plurality of contact electrodes CCE may be removed in the display area AA. The passivation layer 116 covering the solder pattern SDP may be removed in the display area AA.

Since the passivation layer 116 covers the remaining areas while exposing a portion of the plurality of pad electrodes PE, a portion of the plurality of contact electrodes CCE and a portion of the solder pattern SDP, penetration of moisture or impurities flowing into the light emitting device ED may be reduced. For example, the passivation layer 116 may be formed of a single layer or multiple layers including silicon oxide (SiOx) or silicon nitride (SiNx), but implementations of the present disclosure are not limited thereto. For example, the passivation layer 116 may be a protective layer or an insulating layer, but implementations of the present disclosure are not limited thereto. For example, the passivation layer 116 may include a hole exposing the solder pattern SDP and a hole exposing the contact electrode CCE.

In each of the plurality of sub-pixels, the light emitting device ED may be disposed on the solder pattern SDP. The first light emitting device 130 may be disposed in the first sub-pixel SP1. The second light emitting device 140 may be disposed in the second sub-pixel SP2. The third light emitting device 150 may be disposed in the third sub-pixel SP3.

The light emitting device ED may be formed on silicon wafers by means of metal organic vapor deposition (MOCVD), chemical vapor deposition (CVD), plasma-enhanced chemical vapor deposition (PECVD), molecular beam growth (MBE), hydride vapor deposition (HVPE), or sputtering, but implementations of the present disclosure are not limited thereto.

Referring to FIG. 9, the first light emitting device 130 may include an anode 134, a first semiconductor layer 131, an active layer 132, a second semiconductor layer 133, a cathode 135, and an encapsulation layer 136, but implementations of the present disclosure are not limited thereto. For example, the encapsulation layer 136 may not be included in the first light emitting device 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may include a compound semiconductor such as a group III-V or a group II-VI, and may be doped with impurities (or dopants). For example, one of the first semiconductor layer 131 and the second semiconductor layer 133 may be a semiconductor layer doped with n-type impurities, and the other may be a semiconductor layer doped with p-type impurities, but implementations of the present disclosure are not limited thereto. For example, At least one of the first semiconductor layer 131 and the second semiconductor layer 133 may be a layer in which an n-type or p-type impurity is doped into a material such as gallium nitride (GaN), gallium phosphide (GaP), gallium arsenic phosphide (GaAsP), aluminum gallium indium phosphide (AlGaInP), indium aluminum phosphide (InAlP), aluminum gallium nitride (AlGaN), aluminum indium nitride (AlInN), aluminum gallium nitride (AlInGaN), aluminum gallium arsenic (AlGaAs), or gallium arsenic (GaAs), but implementations of the present disclosure are not limited thereto. For example, the n-type impurity may be silicon (Si), germanium (Ge), selenium (Se), carbon (C), tellurium (Te), tin (Sn), or the like, but implementations of the present disclosure are not limited thereto. For example, the p-type impurity may be magnesium (Mg), zinc (Zn), calcium (Ca), strontium (Sr), barium (Ba), beryllium (Be), or the like, but implementations of the present disclosure are not limited thereto.

For example, each of the first semiconductor layer 131 and the second semiconductor layer 133 may be a nitride semiconductor including the n-type impurity and a nitride semiconductor including the p-type impurity, but implementations of the present disclosure are not limited thereto. For example, the first semiconductor layer 131 may be a nitride semiconductor including the p-type impurity, and the second semiconductor layer 133 may be a nitride semiconductor including the n-type impurity, but implementations of the present disclosure are not limited thereto.

The active layer 132 may be disposed between the first semiconductor layer 131 and the second semiconductor layer 133. The active layer 132 may emit light by receiving holes and electrons from the first semiconductor layer 131 and the second semiconductor layer 133. For example, the active layer 132 may be formed of one of a single well structure, a multi-well structure, a single quantum well structure, a multi-quantum well (MQW) structure, a quantum dot structure, and a quantum line structure, but implementations of the present disclosure are not limited thereto. For example, the active layer 132 may be formed of indium gallium nitride (InGaN), or gallium nitride (GaN), but implementations of the present disclosure are not limited thereto.

For another example, the active layer 132 may include a multi-quantum well (MQW) structure having a well layer and a barrier layer having a band gap higher than that of the well layer. For example, the active layer 132 may include InGaN as a well layer, and may include an AlGaN layer as a barrier layer, but implementations of the present disclosure are not limited thereto.

The anode 134 may be disposed between the first semiconductor layer 131 and the solder pattern SDP. For example, the anode 134 may electrically connect the first semiconductor layer 131 to the first electrode CE1. The anode voltage output from the pixel driving circuit PD may be applied to the first semiconductor layer 131 through the signal line TL, the first electrode CE1, and the anode 134. For example, the anode 134 may be formed of a conductive material capable of eutectic bonding with the solder pattern SDP, but implementations of the present disclosure are not limited thereto. For example, the anode 134 may be formed of gold (Au), tin (Sn), tungsten (W), silicon (Si), siver (Ag), titanium (Ti), iridium (Ir), chromium (Cr), indium (In), zinc (Zn), lead (Pb), Nickel (Ni), platinum (Pt), copper (Cu), or alloys thereof, but implementations of the present disclosure are not limited thereto.

The cathode 135 may be disposed on the second semiconductor layer 133. For example, the cathode 135 may electrically connect the second semiconductor layer 133 to the second electrode CE2. The cathode voltage output from the pixel driving circuit PD may be applied to the second semiconductor layer 133 through the contact electrode CCE, the second electrode CE2, and the cathode 135. The cathode 135 may be formed of a transparent conductive material to allow light emitted from the light emitting device ED to be directed to an upper portion of the light emitting device ED, but implementations of the present are not limited thereto. For example, the cathode 135 may be formed of a material such as indium tin oxide (ITO), indium zinc oxide (IZO), indium gallium zinc oxide (IGZO), or the like, but implementations of the present disclosure are not limited thereto.

The encapsulation layer 136 may be disposed on at least a portion of each of the first semiconductor layer 131, the active layer 132, the second semiconductor layer 133, the anode 134, and the cathode 135. For example, the encapsulation layer 136 may surround at least a portion of each of the first semiconductor layer 131, the active layer 132, the second semiconductor layer 133, the anode 134, and the cathode 135.

For example, the encapsulation layer 136 may protect the first semiconductor layer 131, the active layer 132, and the second semiconductor layer 133. For example, the encapsulation layer 136 may be disposed on a side surface of the first semiconductor layer 131, a side surface of the active layer 132, and a side surface of the second semiconductor layer 133.

For example, the encapsulation layer 136 may be disposed on at least a portion of the anode 134 and the cathode 135, for example, on the edge portion (or one side) of the anode 134 and the edge portion (or one side) of the cathode 135. At least a portion of the anode 134 may be exposed by the encapsulation layer 136, and the anode 134 may connect with the solder pattern SDP. For example, at least a portion of the cathode 135 may be exposed by the encapsulation layer 136 and the cathode 135 may connect with the second electrode CE2. For example, the encapsulation layer 136 may be formed of an insulating material such as silicon nitride (SiNx) or silicon oxide (SiOx), but implementations of the present disclosure are not limited thereto.

For another example, the encapsulation layer 136 may have a structure in which a reflective material is distributed in a resin layer, but implementations of the present disclosure are not limited thereto. For example, the encapsulation layer 136 may be manufactured as a reflector having various structures, but implementations of the present disclosure are not limited thereto. Light emitted from the active layer 132 may be reflected upward by the encapsulation layer 136 so that light extraction efficiency may be improved. For example, the encapsulation layer 136 may be a reflective layer, but implementations of the present disclosure are not limited thereto.

According to the present disclosure, the light emitting device ED has been described as a vertical structure, but implementations of the present disclosure are not limited thereto. For example, the light emitting device ED may have a lateral structure or a flip chip structure.

Although the first light emitting device 130 has been described with reference to FIG. 9, the second light emitting device 140 and the third light emitting device 150 may have substantially the same structure as the first light emitting device 130. For example, the second light emitting device 140 and the third light emitting device 150 may have substantially the same configuration as the first semiconductor layer 131, the active layer 132, the second semiconductor layer 133, the anode 134, the cathode 135, and the encapsulation layer 136.

As shown in FIGS. 8 and 9, a first optical layer 117a surrounding the plurality of light emitting devices ED may be disposed in the display area AA. For example, the first optical layer 117a may cover the side surfaces of the plurality of light emitting devices ED and the side surfaces of the plurality of banks BNK in the plurality of sub-pixels. For example, the first optical layer 117a may cover a portion of the passivation layer 116. For example, the first optical layer 117a may cover the second electrode CE2, a portion of the passivation layer 116, and an area between the plurality of light emitting devices ED. The first optical layer 117a may be disposed or covered between the plurality of light emitting devices ED and between the plurality of banks BNK included in one pixel PX. For example, the first optical layer 117a may extend in the first direction X, and the plurality of first optical layers 117a may be spaced apart from each other in the second direction Y in a plan view. For example, the first optical layer 117a may be disposed between the passivation layer 116 and the second electrode CE2 to surround the side surface of the light emitting device ED and the side surface of the bank BNK, but implementations of the present disclosure are not limited thereto. For example, the first optical layer 117a may be a diffusion layer, a sidewall diffusion layer, or the like, but implementations of the present disclosure are not limited thereto.

The first optical layer 117a may include an organic insulating material in which fine particles are distributed, but implementations of the present disclosure are not limited thereto. For example, the first optical layer 117a may be formed of siloxane in which fine metal particles such as titanium dioxide (TiO₂) particles are distributed, but implementations of the present disclosure are not limited thereto. Light from the plurality of light emitting devices ED may be scattered by fine particles distributed in the first optical layer 117a and emitted to an outside of the display panel 100. Accordingly, the first optical layer 117a may improve extraction efficiency of light emitted from the plurality of light emitting devices ED.

For example, the first optical layer 117a may be disposed in each of the plurality of pixels PX or may be disposed in some pixels PX disposed in the same row, but implementations of the present disclosure are not limited thereto. For example, the first optical layer 117a may be disposed in each of the plurality of pixels PX, or the plurality of pixels PX may share one first optical layer 117a. For another example, each of the plurality of sub-pixels may separately include a first optical layer 117a, but implementations of the present disclosure are not limited thereto.

According to the present disclosure, the second optical layer 117b may be disposed on the passivation layer 116 in the display area AA. For example, the second optical layer 117b may surround the first optical layer 117a. For example, the second optical layer 117b may be in contact with a side surface of the first optical layer 117a. For example, the second optical layer 117b may be disposed in an area between the plurality of pixels PX. However, implementations of the present disclosure are not limited thereto. For example, the second optical layer 117b may be a diffusion layer, a window diffusion layer, or the like, but implementations of the present disclosure are not limited thereto.

The second optical layer 117b may be formed of an organic insulating material, but implementations of the present disclosure are not limited thereto. The second optical layer 117b may be formed of the same material as the first optical layer 117a, but implementations of the present disclosure are not limited thereto. For example, the first optical layer 117a may include fine particles, and the second optical layer 117b may not include fine particles. For example, the second optical layer 117b may be formed of siloxane, but implementations of the present disclosure are not limited thereto.

For example, a thickness of the first optical layer 117a may be less than a thickness of the second optical layer 117b, but implementations of the present disclosure are not limited thereto. Accordingly, in a plan view, an area in which the first optical layer 117a is disposed may include a concave portion recessed from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of light emitting devices ED. For example, the second electrode CE2 may include a transparent conductive oxide such as indium tin oxide (ITO) or indium zinc oxide (IZO), but implementations of the present disclosure are not limited thereto. For example, the second electrode CE2 may be in contact with the cathode 135. For example, the second electrode CE2 may overlap the entire first optical layer 117a, and may overlap a portion of the second optical layer 117b.

The second electrode CE2 may extend continuously in the first direction of the substrate 110. Accordingly, the second electrode CE2 may be connected in common to the plurality of pixels PX arranged in the first direction of the substrate 110. For example, the second electrode CE2 may be connected in common to the plurality of pixels PX.

According to the present disclosure, the second electrode CE2 may continuously extend on the first optical layer 117a, the second optical layer 117b, and the light emitting device ED. The area in which the first optical layer 117a is disposed may include the concave portion recessed from the upper surface of the second optical layer 117b. Accordingly, since a first portion of the second electrode CE2 disposed on the first optical layer 117a is disposed along the concave portion, the first portion may be disposed at a lower position than a second portion of the second electrode CE2 disposed on the second optical layer 117b.

The third optical layer 117c may be disposed on the second electrode CE2. The third optical layer 117c may overlap the plurality of light emitting devices ED and the first optical layer 117a. For example, the third optical layer 117c may not overlap the second optical layer 117b. Since the third optical layer 117c is disposed on the second electrode CE2 and the plurality of light emitting devices ED, spot (of mura) that may occur in some of the plurality of light emitting devices ED may be improved. For example, when the plurality of light emitting devices ED are transferred on the substrate 110 of the display panel 100, a region in which an gap between the plurality of light emitting devices ED is not uniform due to a process deviation, or the like may be formed. When the gap between the plurality of light emitting devices ED is not uniform, a light emitting area of each of the plurality of light emitting devices ED may be non-uniformly disposed, and thus a spot (or mura) may be recognized by a user. Accordingly, since the third optical layer 117c for uniformly diffusing light on an upper portion of the plurality of light emitting devices ED is formed, it is possible to reduce visibility of light emitted from some light emitting devices ED as spots (or mura). Therefore, since the light emitted from the plurality of light emitting devices ED is uniformly diffused by the third optical layer 117c and extracted to the outside of the display panel 100, the luminance uniformity of the display device may be improved.

The third optical layer 117c may be formed of an organic insulating material in which fine particles are distributed, but implementations of the present disclosure are not limited thereto. For example, the third optical layer 117c may be formed of siloxane in which fine metal particles such as titanium dioxide (TiO2) particles are distributed, but implementations of the present disclosure are not limited thereto. For example, the third optical layer 117c may be formed of the same material as the first optical layer 117a, but implementations of the present disclosure are not limited thereto. For example, the third optical layer 117c may be a diffusion layer, an upper diffusion layer, or the like, but implementations of the present disclosure are not limited thereto.

According to the present disclosure, light from the plurality of light emitting devices ED may be scattered by fine particles distributed in the third optical layer 117c and emitted to the outside of the display panel 100. The third optical layer 117c may evenly mix the light emitted from the plurality of light emitting devices ED to further improve luminance uniformity of the display device. In addition, light extraction efficiency of the display device may be improved by the light scattered from the plurality of fine particles, and thus the display device may be driven at a low power.

In the display area AA, a black matrix BM may be disposed on the second electrode CE2, the first optical layer 117a, the second optical layer 117b, and the third optical layer 117c. For example, the black matrix BM may fill a contact hole of the second optical layer 117b. Since the black matrix BM may cover the display area AA, color mixture of light of the plurality of sub pixels and reflection of external light may be reduced. For example, since the black matrix BM is disposed within a contact hole in which the second electrode CE2 and the contact electrode CCE are connected, light leakage between the plurality of adjacent sub-pixels may be prevented.

For example, the black matrix BM may be formed of an opaque material, but implementations of the present disclosure are not limited thereto. For example, the black matrix BM may be an organic insulating material to which a black pigment or a black dye is added, but implementations of the present disclosure are not limited thereto.

Referring to FIG. 8, a cover layer 118 may be disposed on the black matrix BM in the display area AA. The cover layer 118 may protect an element under the cover layer 118, for example, the cover layer 118 may be formed of an organic insulating material, but implementations of the present disclosure are not limited thereto. For example, the cover layer 118 may be formed of a photo resist, polyimide (PI), a photo acryl-based material, or the like, but implementations of the present disclosure are not limited thereto. For example, the cover layer 118 may be an overcoating layer, an insulating layer, or the like, but implementations of the present disclosure are not limited thereto.

A polarizing layer 280 may be disposed on the cover layer 118 via a first adhesive layer 291. A cover component 120 may be disposed on the polarizing layer 280 via a second adhesive layer 295. For example, the first adhesive layer 291 and the second adhesive layer 295 may include an optically clear adhesive (OCA), an optically clear resin (OCR), a pressure sensitive adhesive (PSA) or the like, but implementations of the present disclosure are not limited thereto.

According to the present disclosure, the plurality of pad electrodes PE may be disposed on the third insulating layer 115c in the second non-display area NA2. For example, a portion of the plurality of pad electrodes PE may be exposed by the passivation layer 116. For example, the plurality of pad electrodes PE may be electrically connected to the 2-4th connection line 122d through a contact hole of the third insulating layer 115c.

An adhesive film ACF may be disposed on the plurality of pad electrodes PE. The adhesive film ACF may be an adhesive layer in which conductive balls are distributed in an insulating material, but implementations of the present disclosure are not limited thereto. When heat or pressure is applied to the adhesive film ACF, the conductive ball may have conductive characteristics in a region to which heat or pressure is applied. An adhesive film ACF may be disposed between the plurality of pad electrodes PE and the flexible circuit board (or flexible film) 170, so that a flexible circuit board (or flexible film) 170 may be attached to or bonded to the plurality of pad electrodes PE. For example, the adhesive film ACF may be an anisotropic conductive film (ACF), but implementations of the present disclosure are not limited thereto.

The flexible circuit board (or flexible film) 170 may be disposed on the adhesive film ACF. The flexible circuit board (or flexible film) 170 may be electrically connected to the plurality of pad electrodes PE through the adhesive film ACF. Therefore, signals output from the flexible circuit board (or flexible film) 170 and the printed circuit board 160 may be transmitted to the pixel driving circuit PD of the display area AA through the plurality of pad electrodes PE, the 2-4th connection line 122d, the 2-3th connection line 122c, the 2-ith connection line 122b, and the 2-1th connection line 122a

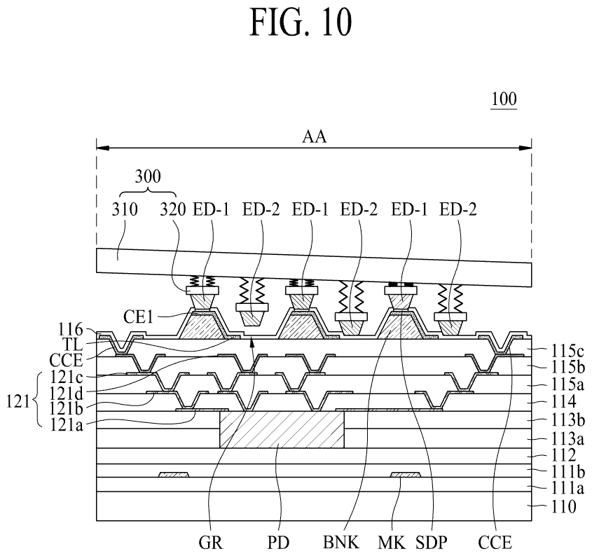

FIG. 10 is a process cross-sectional view illustrating a transfer process of a light emitting device according to an implementation of the present disclosure.

As can be seen from FIG. 10, a plurality of light emitting devices ED-1 and ED-2 fixed to a transfer device 300 may be transferred to individual sub-pixels of the display area AA after being moved above the display panel 100.

The transfer device 300 may include a support component 310 and a plurality of pickers 320 connected to the support component 310. The plurality of light emitting devices ED-1 and ED-2 may be fixed to the plurality of pickers 320. The plurality of light emitting devices ED-1 and ED-2 may be moved above the display area AA of the display panel 100 while being fixed by the plurality of pickers 320. Thereafter, the plurality of light emitting devices ED-1 and ED-2 may be transferred on a plurality of solder patterns SDP disposed on the bank BNK.

In order to increase a transfer process speed, a single pick and multi-place method may be used when transferring the plurality of light emitting devices ED-1 and ED-2. Specifically, a transfer process for the plurality of light emitting devices ED-1 and ED-2 may be sequentially implemented by simultaneously lifting the plurality of light emitting devices ED-1 and ED-2 using the plurality of pickers 320 and then transferring the plurality of light emitting devices ED-1 and ED-2.

For example, a plurality of light emitting devices ED-1 in a first set may be transferred on the plurality of solder patterns SDP disposed on a plurality of banks BNK in a first set through a first transfer process. The plurality of light emitting devices ED-2 in a second set that are not transferred may be moved to corresponding positions by the transfer device 300. A plurality of light emitting devices ED-2 in a second set that are not transferred may be transferred on the plurality of solder patterns SDP disposed on a plurality of banks BNK in a second set through a second transfer process.

In this case, a distance between the plurality of pickers 320 may be smaller than a distance between the plurality of banks BNK. Accordingly, when a transfer process for the light emitting devices ED-1 in the first set is performed by the first transfer process, the light emitting devices ED-2 in the second set is positioned in a region between the plurality of banks BNK in the first set.

During the transfer process, transfer errors may occur due to various types of process errors. As described above, during the first transfer process, the light emitting devices ED-2 in the second set should not be transferred. However, there may be a problem that some of the light emitting devices ED-2 in the second set are incorrectly transferred to a region between the plurality of banks BNK in the second set. For example, the transfer error as described above may occur due to the process error such as poor flatness of the third insulating layer 115c under the bank BNK, poor pattern of the bank BNK, or incorrect horizontal adjustment of the support component 310 of the transfer device 300.

When a height of the bank BNK is increased, an occurrence of the above-described transfer error may be reduced. However, when the height of the bank BNK is increased, a stability of the bank BNK may be decreased. Accordingly, it is necessary to increase a width of the bank BNK together with the height of the bank BNK. However, when the width of the bank BNK increases, a distance between banks BNK may decrease and the occurrence of transfer error may rather increase. Hereinafter, various implementations capable of reducing the occurrence of transfer error will be described.

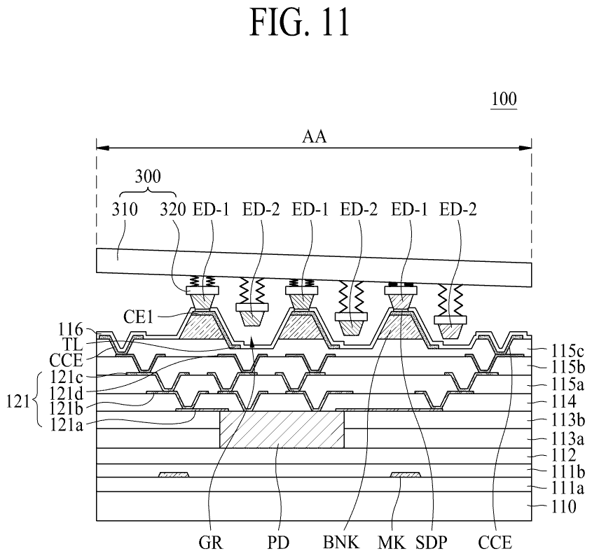

FIG. 11 is a process cross-sectional view illustrating a transfer process of a light emitting device according to an implementation of the present disclosure.

As shown in FIG. 11, according to an implementation of the present disclosure, a groove GR is disposed in a region between the plurality of banks BNK. For example, the groove GR is disposed in the third insulating layer 115c between the plurality of banks BNK. A height of an upper surface of a region of the third insulating layer 115c overlapping the plurality of banks BNK may be higher than a height of an upper surface of at least a partial region of the third insulating layer 115c not overlapping the plurality of banks BNK, that is, a height of an upper surface of the groove GR.

The signal line TL extends along a side surface of the bank BNK to an inside of the groove GR. For example, the signal line TL extends to the inside of the groove GR in the third insulating layer 115c.

In addition, the passivation layer 116 disposed on the signal line TL also extends inside the groove GR. For example, the passivation layer 116 may cover the groove GR in the third insulating layer 115c. In this case, a groove GR having a shape corresponding to at least a portion of the groove GR in the third insulating layer 115c may be disposed on an upper surface of the passivation layer 116. A height of an upper surface of a region of the third insulating layer 115c overlapping the plurality of banks BNK may be higher than a height of an upper surface of at least a portion of a region of the passivation layer 116 that does not overlap the plurality of banks BNK.

Such a structure may be obtained by sequentially performing a process of applying the third insulating layer 115c, a process of forming the groove GR through a patterning process, a process of patterning the bank BNK in a region except for a region of the groove GR, and a process of sequentially forming the signal line TL and the passivation layer 116.

Alternatively, such a structure may be obtained by sequentially performing a process of applying the third insulating layer 115c, a process of patterning the bank BNK, a process of forming the groove GR in a region of the third insulating layer 115c between the banks BNK, and a process of sequentially patterning the signal line TL and the passivation layer 116.

In the case of FIG. 11, for example, when the plurality of the light emitting devices ED-1 in the first set is transferred on the solder patterns SDP disposed on the plurality of banks BNK in the first set by the first process, the plurality of the light emitting devices ED-2 in the second set that that are not transferred are aligned at a position overlapping the groove GR disposed in a region between the plurality of banks BNK in the first set.

Therefore, due to the groove GR, since a distance from the light emitting devices ED-2 in the second set to the passivation layer 116 is far, even if various types of process errors occur during the first transfer process, a problem of incorrect transfer of the light emitting devices ED-2 in the second set may be reduced.

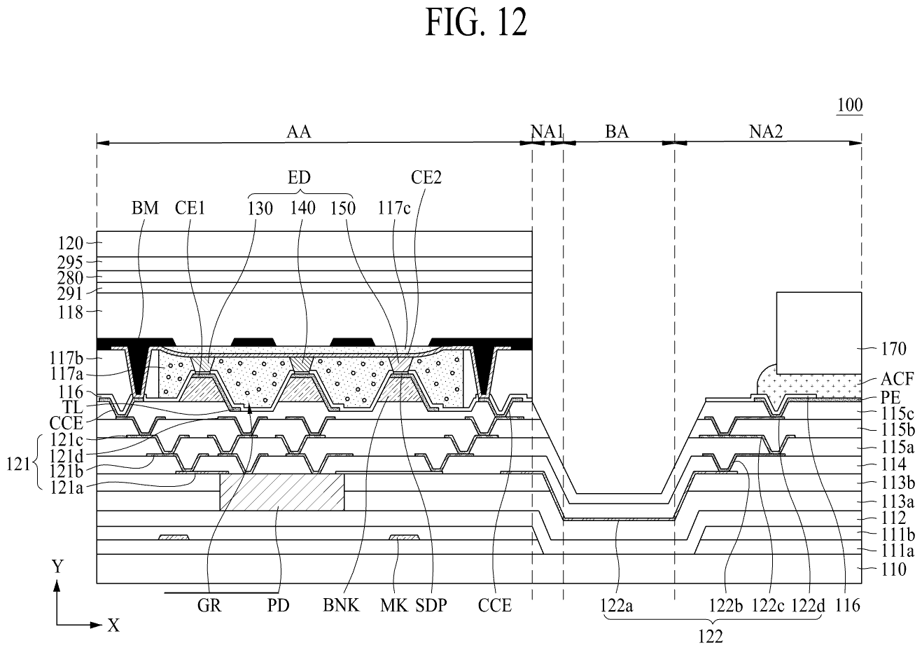

FIG. 12 is a cross-sectional view of a display device according to an implementation of the present disclosure, and this relates to a display device to which the transfer process according to FIG. 11 described above is applied. In an implementation according to FIG. 12, except that the groove GR is formed in the display area AA, the structures of the non-display areas NA1 and NA2 and the bending area BA are the same as those of the above-described implementation according to FIG. 8. Accordingly, the same reference numerals are assigned to the same configurations, and different configurations will be described below.

As shown in FIG. 12, according to an implementation of the present disclosure, a groove GR may be disposed on an upper surface of a third insulating layer 115c between a plurality of banks BNK in a display area AA. A signal line TL extends along a side surface of the bank BNK to an inside of the groove GR in the third insulating layer 115c. A passivation layer 116 may cover the groove GR in the third insulating layer 115c.

A first optical layer 117a may extend to the inside of the groove GR, and the inside of the groove GR on a passivation layer 116 may be filled with the first optical layer 117a. A second optical layer 117b may also extend to the inside of the groove GR, and the inside of the groove GR on the passivation layer 116 may be filled with a combination of the first optical layer 117a and the second optical layer 117b.

The groove GR may be formed to overlap the black matrix BM.

A width of the groove GR may be the same as a distance between two adjacent banks BNK. For example, one end of the groove GR, for example, a left end of the groove GR, may coincide with one end of one bank BNK, for example, a right end of a left bank BNK, and the other end of the groove GR, for example, a right end of the groove GR, may coincide with one end of the other adjacent bank BNK, for example, a left end of a right bank BNK.

A depth of the groove GR may be small than a thickness of the third insulating layer 115c. However, the present disclosure is not limited thereto, and the depth of the groove GR may be greater than the thickness of the third insulating layer 115c. For example, the groove GR may penetrate an entire of third insulating layer 115c and may be formed to a part of the second insulating layer 115b under the third insulating layer 115c.

A shape of the groove GR may have a trapezoidal structure in which a width of the groove GR is decreased toward a lower part, but is not limited thereto.

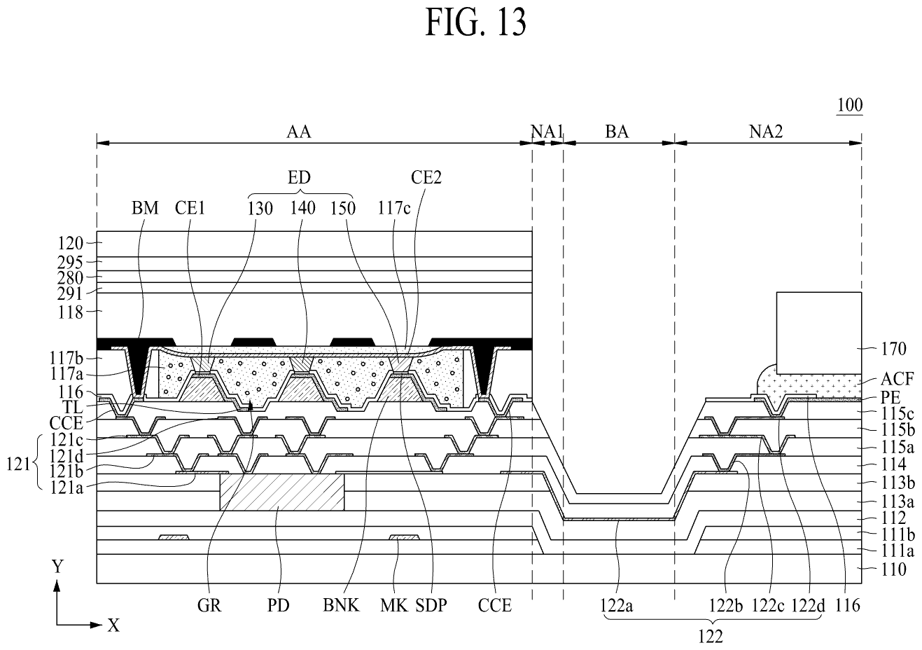

FIG. 13 is a cross-sectional view of a display device according to an implementation of the present disclosure, which is the same as an implementation according to FIG. 12 described above, except that a width of the groove GR is changed. Accordingly, the same reference numerals are assigned to the same configurations, and different configurations are to be described below.

As may be seen from FIG. 13, a width of the groove GR may be smaller than a distance between two adjacent banks BNK. Accordingly, one end of the groove GR may be formed on a right side of one end of one bank BNK, and the other end of the groove GR may be formed on a left side of one end of the other bank BNK. For example, a left end of the groove GR may be formed on a right side of a right end of a left bank BNK, and a right end of the groove GR may be formed on a left side of a left end of a right bank BNK.

FIG. 14 is a plan view of a display device according to an implementation of the present disclosure. FIG. 14 is the same as an implementation according to FIG. 7 described above except that a first groove GR1 is added. Accordingly, the same reference numerals are assigned to the same configurations, and different configurations are to be described below.

As shown in FIG. 14, a plurality of first grooves GR1 are disposed in a region between a first sub-pixel SP1 and a second sub-pixel SP2, a region between the second sub-pixel SP2 and a third sub-pixel SP3, and a region between the third sub-pixel SP3 and the first sub-pixel SP1.

The plurality of first grooves GR1 are disposed in a region between a first light emitting device 130 and a second light emitting device 140, a region between the second light emitting device 140 and a third light emitting device 150, and a region between the third light emitting device 150 and the first light emitting device 130.

The plurality of first grooves GR1 are not connected to each other but are spaced apart from each other.

The first groove GR1 may overlap a signal line TL. For example, the first groove GR1 disposed in the region between the first sub-pixel SP1 and the second sub-pixel SP2 may overlap a second signal line TL2 and a third signal line TL3. The first groove GR1 disposed in the region between the second sub-pixel SP2 and the third sub-pixel SP3 may overlap a fourth signal line TL4 and a fifth signal line TL5. The first groove GR1 disposed in the region between the third sub-pixel SP3 and the first sub-pixel SP1 may overlap the sixth signal line TL6 and the first signal line TL1.

The first groove GR1 may have a rectangular structure having a first width x1 in a horizontal direction and a first length y1 in a vertical direction.

The first width x1 of the first groove GR1 may be equal to or less than a distance between two adjacent banks BNK. The first width x1 of the first groove GR1 may be greater than a sum of widths of the two signal lines TL1 and TL2 in the horizontal direction, but is not limited thereto.

The first length y1 of the first groove GR1 may be, for example, greater than a sum of lengths of a pair of first light emitting devices 130 in the vertical direction. That is, the first length y1 of the first groove GR1 may be greater than a sum of lengths of the 1-1th light emitting device 130a and the 1-2th light emitting device 120b in the vertical direction. The first length y1 of the first groove GR1 may be equal to or greater than a length of the bank BNK in the vertical direction.

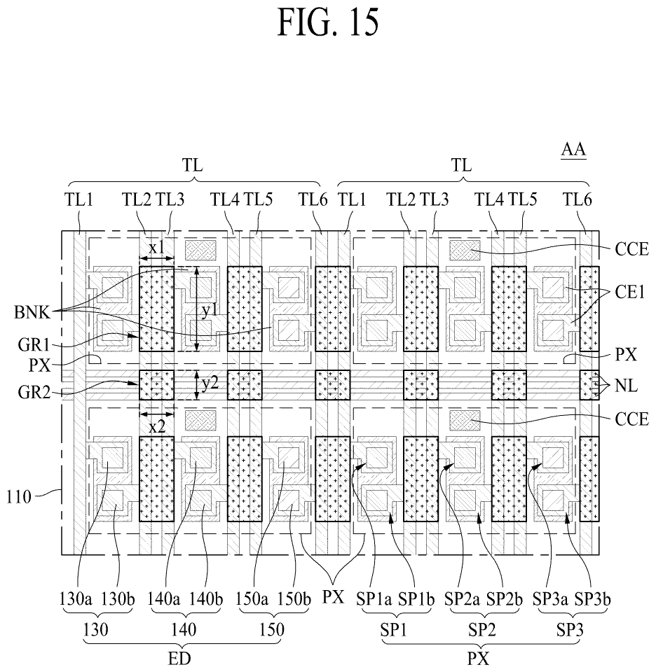

FIG. 15 is a plan view of a display device according to an implementation of the present disclosure. FIG. 15 is the same as an implementation of FIG. 14 described above except that a second groove GR2 is added.

As may be seen from FIG. 15, a plurality of second grooves GR2 may be disposed in a region between one row in which a plurality of pixels PX are arranged and another adjacent row in which the plurality of pixels PX are arranged.

The plurality of second grooves GR2 may be disposed between the plurality of first grooves GR1. The second groove GR2 is spaced apart from the first groove GR1. For example, the second groove GR2 may be disposed in a region between the first groove GR1 disposed in one row in which the plurality of pixels PX are arranged and the first groove GR1 disposed in another adjacent row in which the plurality of pixels PX are arranged.

Like the first groove GR1 described above, the second groove GR2 may overlap a signal line TL. In addition, the plurality of second grooves GR2 may overlap a plurality of communication lines NL.

The second groove GR2 may have a rectangular structure having a second width x2 in the horizontal direction and a second length y2 in the vertical direction. The second width x2 of the second groove GR2 may be the same as the first width x1 of the first groove GR1. The second length y2 of the second groove GR2 may be different from the first length y1 of the first groove GR1.

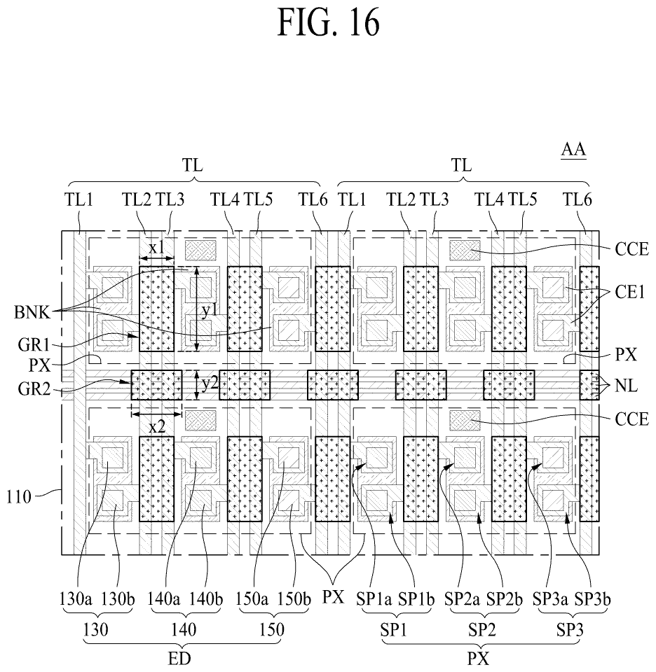

FIG. 16 is a plan view of a display device according to an implementation of the present disclosure. FIG. 16 is the same as an implementation of FIG. 15 described above except that the second width x2 of the second groove GR2 is changed.

As shown in FIG. 16, the second width x2 of the second groove GR2 may be greater than the first width x1 of the first groove GR1. For example, the second width x2 of the second groove GR2 may be greater than a distance between two adjacent banks BNK.

As the second width x2 of the second groove GR2 increases, even if an error occurs during the transfer process of the light emitting device ED, a possibility of the light emitting device ED being transferred to an undesired position decreases.

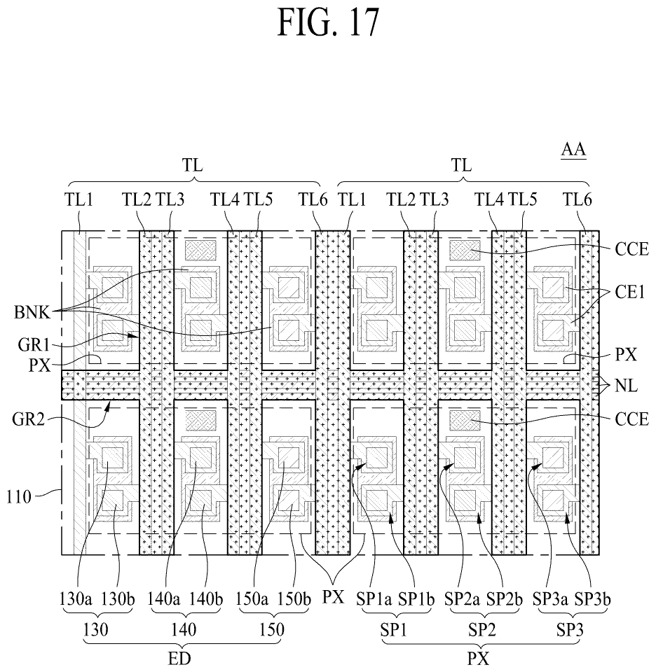

FIG. 17 is a plan view of a display device according to an implementation of the present disclosure.

As shown in FIG. 17, the first groove GR1 is continuous in a vertical direction in each of a region between a first sub-pixel SP1 and a second sub-pixel SP2, a region between the second sub-pixel SP2 and a third sub-pixel SP3, and a region between the third sub-pixel SP3 and the first sub-pixel SP1. That is, the first groove GR1 in the region between the first sub-pixel SP1 and the second sub-pixel SP2, the first groove GR1 in the region between the second sub-pixel SP2 and the third sub-pixel SP3, and the first groove GR1 in the region between the third sub-pixel SP3 and the first sub-pixel SP1 are connected to each other.

In addition, the second groove GR2 is continuous in the horizontal direction in a region between one row in which the plurality of pixels PX are arranged and the other adjacent row in which the plurality of pixels PX are arranged.

Thus, the plurality of first grooves GR1 and the plurality of second grooves GR2 may be connected to each other at cross-connections to form a mesh structure.

As an area where the grooves GR1 and GR2 are formed increases by crossing each other to form a mesh structure, a possibility of the light emitting device ED being transferred to an undesired position decreases even if an error occurs during the transfer process of the light emitting device ED.

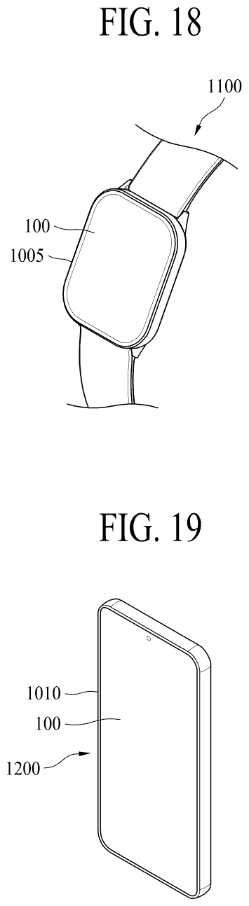

FIGS. 18 to 21 are diagrams illustrating devices to which a display device according to implementations of the present disclosure is applied.

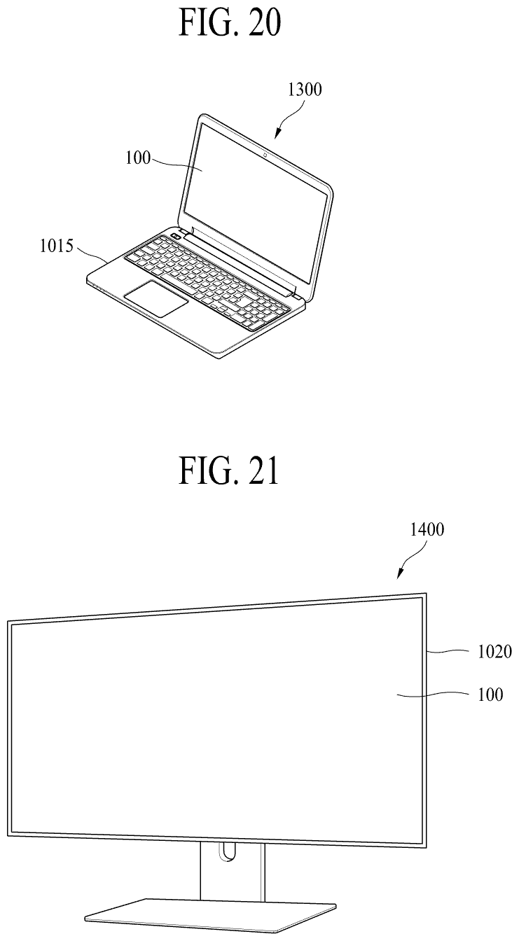

Referring to FIGS. 18 to 21, the display device according to implementations of the present disclosure may be included in various devices or electronic devices. For example, various electronic devices may include a wearable device 1100 as shown in FIG. 18, a mobile device 1200 as shown in FIG. 19, a laptop 1300 as shown in FIG. 20, and a monitor or TV 1400 as shown in FIG. 21, but implementations of the present disclosure are not limited thereto.

Each of the wearable device 1100, the mobile device 1200, the laptop 1300, and the monitor or TV 1400 may include a case unit 1005, 1010, 1015, and 1020 and a display panel 100 and a display device 1000 according to the above-described implementations of the present disclosure.

For example, the display device according to an implementation of the present disclosure includes a mobile device, a video phone, a smart watch, a watch phone, a wearable device, a foldable device, a rollable device, a bendable device, a flexible device, a curved device, a sliding device, a variable device, an electronic notebook, an electronic book, a portable multimedia player (PMP), personal digital assistant (PDA), an MP3 player, a mobile medical device, a desktop PC, a laptop PC, a netbook computer, a workstation, a navigation, a vehicle display, a theater display, a television, a wall paper device, a signage device, a game device, a laptop, a game device, a monitor, a camera, a camcorder or a home appliance.

It will be apparent to those skilled in the art that the present disclosure described above is not limited by the above-described implementations and the accompanying drawings and that various substitutions, modifications and variations can be made in the present disclosure without departing from the spirit or scope of the disclosures. Consequently, the scope of the present disclosure is defined by the accompanying claims and it is intended that all variations or modifications derived from the meaning, scope and equivalent concept of the claims fall within the scope of the present disclosure.

What is claimed is:

1. A display device comprising:
a substrate including a display area and a non-display area;
a pixel driving circuit in the display area on the substrate;
an insulating layer on the pixel driving circuit;
a plurality of banks including a first bank and a second bank; and
a plurality of light emitting devices including a first light emitting device on the first bank and a second light emitting device on the second bank,
wherein the first bank and the second bank are disposed on the insulating layer,
wherein the first light emitting device overlaps the first bank and the second light emitting device overlaps the second bank, and
wherein the insulating layer includes a groove in a region between the first bank and the first bank.

2. The display device of claim 1, wherein a height of an upper surface of the insulating layer overlapping the first bank is higher than the height of the upper surface of the groove of the insulating layer not overlapping the first bank.

3. The display device of claim 1, further comprising:
a first electrode disposed between the first light emitting device and the first bank; and
a signal line disposed on the insulating layer and electrically connecting the first electrode and the pixel driving circuit,
wherein the signal line extends to an inside of the groove of the insulating layer.

4. The display device of claim 3, further comprising a passivation layer on the signal line, and
wherein the passivation layer extends to an inside of the groove of the insulating layer.

5. The display device of claim 4, wherein the first electrode includes:
a first conductive layer made of a reflective material; and
a second conductive layer disposed on the first conductive layer and exposing a part of an upper surface of the first conductive layer,
wherein the passivation layer covers the part of the upper surface of the first conductive layer.

6. The display device of claim 1, further comprising:
a second electrode disposed on the plurality of light emitting devices and electrically connected to the plurality of light emitting devices; and
a first optical layer disposed under the second electrode and covering a side surface of the plurality of light emitting devices and the side surface of the plurality of banks,
wherein the first optical layer fills an inside of the groove.

7. The display device of claim 6, further comprising:
a second optical layer in contact with a side surface of the first optical layer
a contact electrode disposed on the insulating layer and electrically connecting the second electrode and the pixel driving circuit; and
a plurality of first connection lines electrically connected to each other through a contact hole in the insulating layer and electrically connecting the contact electrode and the pixel driving circuit,
wherein the second electrode is connected to the contact electrode through the contact hole in the second optical layer.

8. The display device of claim 6, further comprising a black matrix on the second electrode and a third optical layer between the second electrode and the black matrix,
wherein the black matrix overlaps the groove.

9. The display device of claim 6, further comprising a cover layer on the second electrode, a polarizing layer on the cover layer, and a cover component on the polarizing layer.

10. The display device of claim 1, further comprising:
a pad electrode on the insulating layer in the non-display area; and
a plurality of second connection lines electrically connected to each other through a contact hole in the insulating layer and electrically connecting the pad electrode and the pixel driving circuit.

11. A display device comprising:
a display area;
a non-display area disposed outside the display area;
a plurality of pixels disposed in the display area and including a first sub-pixel and a second sub-pixel;
a plurality of banks including a first bank in the first sub-pixel and a second bank in the second sub-pixel; and
a plurality of light emitting devices including a first light emitting device overlapping the first bank and a second light emitting device overlapping the second bank,
wherein the first sub-pixel and the second sub-pixel are arranged in a first direction, and
wherein a first groove is disposed in a region between the first sub-pixel and the second sub-pixel.

12. The display device of claim 11, wherein a width of the first groove in the first direction is smaller than a distance between the first bank and the second bank.

13. The display device of claim 11, wherein the plurality of pixels include a first pixel and a second pixel,
wherein the first pixel and the second pixel are arranged in a second direction crossing the first direction, and
wherein the first groove of the first pixel and the first groove of the second pixel are spaced apart from each other.

14. The display device of claim 13, further comprising a second groove disposed a region between the first groove of the first pixel and the first groove of the second pixel,
wherein the second groove is spaced apart from the first groove.

15. The display device of claim 11, wherein the plurality of pixels include a first pixel and a second pixel,
the first pixel and the second pixel are arranged in a second direction crossing the first direction,
a second groove is disposed in a region between the first pixel and the second pixel, and
the first groove in the first pixel, the first groove in the second pixel, and the second groove disposed at a boundary between the first pixel and the second pixel are connected to each other.

16. The display device of claim 11, further comprising a signal line electrically connected to the first light emitting device and extending in a second direction crossing the first direction,
wherein the signal line overlaps the first groove.

17. The display device of claim 11, wherein the plurality of pixels further include a third sub-pixel adjacent to the second sub-pixel,
wherein the first groove is disposed in a region between the second sub-pixel and the third sub-pixel,
wherein the second light emitting device includes a first sub-light emitting device and a second sub-light emitting device spaced apart from each other,
wherein the first sub-light emitting device is electrically connected to a first signal line disposed between the first sub-pixel and the second sub-pixel,
wherein the second sub-light emitting device is electrically connected to a second signal line disposed between the second sub-pixel and the third sub-pixel, and
wherein the first signal line and the second signal line extend side by side in a second direction crossing the first direction to overlap the first groove.

18. The display device of claim 11, further comprising a first electrode electrically connected to the first light emitting device,
wherein an entire area of the first light emitting device overlaps the first bank, and
wherein a partial region of the first electrode overlaps the first bank, and a remaining region of the first electrode does not overlap the first bank.

19. The display device of claim 11, wherein the plurality of pixels include a first pixel and a second pixel,
wherein the first pixel and the second pixel are arranged in a second direction crossing the first direction,
wherein it further includes a first cathode electrically connected to the plurality of light emitting devices in the first pixel and a second cathode electrically connected to the plurality of light emitting devices in the second pixel, and
wherein the first cathode and the second cathode are spaced apart from each other with respect to a region between the first pixel and the second pixel.

20. The display device of claim 11, wherein the non-display area includes a first non-display area surrounding the display area, a bending area extending from one side of the first non-display area, and a second non-display area extending from the bending area,
wherein a pad part is disposed in the second non-display area,
wherein a plurality of link lines are disposed in the non-display area and extend from the pad part of the second non-display area to the bending area and the first non-display area,
wherein a plurality of driving lines are disposed in the display area and are connected to the plurality of link lines, and
wherein the plurality of driving lines are connected to a plurality of pixel driving circuits in the display area.
